(19) United States
(12) Patent Application Publication
(10) Pub. No.: US 2012/0007637 A1
(43) Pub. Date: Jan. 12, 2012

(54) LOAD DRIVER SYSTEM

(76) Inventor: Daisuke FUKUDA, Kyoto (JP)

(21) Appl. No.: 13/178,230

(22) Filed: Jul. 7, 2011

(30) Foreign Application Priority Data
Jul. 7, 2010 (JP) 2010-154652

(51) Int. Cl. H03K 3/00

(52) U.S. Cl. 327/110

(57) ABSTRACT

A first driver device and a first diode are connected in parallel between an output node and a first voltage node. A second driver device and a second diode are connected in parallel between the output node and a second voltage node. When a first switching time comes, a first drive control section switches the first driver device from the off state to the on state after detecting that an output voltage at the output node reaches a predetermined first reference voltage. When a second switching time comes, the first drive control section switches the first driver device from the on state to the off state. A second drive control section switches the second driver device from the on state to the off state when the first switching time comes, and switches the second driver device from the off state to the on state when the second switching time comes.

### CROSS-REFERENCE TO RELATED APPLICATION

This application claims priority to Japanese Patent Application No. 2010-154652 filed on Jul. 7, 2010, the disclosure of which including the specification, the drawings, and the claims is hereby incorporated by reference in its entirety.

### BACKGROUND

The present disclosure relates to load driver systems for driving inductive loads, and more particularly to synchronous rectification driving.

A synchronous rectification driving method is known as a method for efficiently driving an inductive load such as a motor. A load driver system that drives an inductive load with such a synchronous rectification driving method includes a low-side driver device and a high-side driver device connected between a ground node and a power supply node in series, and also includes a low-side freewheeling diode connected in parallel with the low-side driver device and a high-side freewheeling diode connected in parallel with the high-side driver device. To reduce power consumption in driving an inductive load with the synchronous rectification driving method, it is desirable to reduce the period (i.e., a dead time) from when one of the low-side driver device and the high-side driver device is switched from the on state to the off state to when the other driver device is switched from the off state to the on state. However, if the dead time is extremely short, both of the low-side driver device and the high-side driver device might turn on at the same time to cause shoot-through current. For this reason, the dead time is set at a level at which no shoot-through current occurs even with characteristic variations in manufacturing processes or variations in output conditions (e.g., variations in temperature or a power supply voltage). Thus, it is difficult to reduce power consumption by reducing the dead time.

To solve the problem set forth above, Japanese Patent Publication No. H03-293995 proposes a synchronous rectification driving method which can prevent shoot-through current and can reduce a dead time. In a driver circuit described in Japanese Patent Publication No. H03-293995, when one of a low-side driver device and a high-side driver device is switched from the on state to the off state and then the gate-source voltage of this switched driver device falls below a reference voltage, the other driver device is switched from the off state to the on state. The reference voltage is set slightly lower than a threshold voltage of the low-side driver device (or the high-side driver device).

### SUMMARY

In the driver circuit described in Japanese Patent Publication No. H03-293995, however, the gate-source voltages of the low-side driver device and the high-side driver device easily vary due to disturbing noise or other factors, and thus, the time when the gate-source voltage of the low-side driver device (or the high-side driver device) falls below the reference voltage easily changes. In addition, when the threshold voltages of the low-side driver device and the high-side driver device vary due to manufacturing variations or temperature variations, the time when switching of the low-side driver device (or the high-side driver device) from the on state to the off state is completed also varies. As a result, a time difference occurs between the time when the gate-source voltage of the low-side driver device (or the high-side driver device) falls below the reference voltage and the time when switching of the low-side driver device (or the high-side driver device) from the on state to the off state is completed. For example, if the threshold voltage of the low-side driver device is lower than the reference voltage, switching of the low-side driver device from the on state to the off state has not been completed yet even when the gate-source voltage of the low-side driver device falls below the reference voltage.

As described above, since a time difference often occurs between the time when the gate-source voltage of the low-side driver device (or the high-side driver device) falls below the reference voltage and the time when switching of the low-side driver device (or the high-side driver device) from the on state to the off state is completed, it is difficult to accurately set the duration of the dead time. For example, it is difficult to set the duration of the dead time at an ideal length (e.g., the minimum duration sufficient to prevent occurrence of shoot-through current).

It is therefore an object of the present disclosure to provide a load driver system in which the duration of a dead time can be accurately set.

In an aspect of the present disclosure, a load driver system is a system for driving an inductive load including: a first driver device and a first diode connected in parallel between an output node and a first voltage node, the output node being connected to the inductive load, the first voltage node being configured to receive a first voltage; a second driver device and a second diode connected in parallel between the output node and a second voltage node, the second voltage node being configured to receive a second voltage; a first drive control section configured to switch the first driver device from an off state to an on state, after detecting that an output voltage at the output node reaches a predetermined first reference voltage, when a first switching time comes, and to switch the first driver device from the on state to the off state when a second switching time comes; and a second drive control section configured to switch the second driver device from an on state to an off state when the first switching time comes, and to switch the second driver device from the off state to the on state when the second switching time comes.

In the load driver system, the output voltage varies according to on/off of the first and second driver devices. Accordingly, even when the threshold voltages of the first and second driver devices vary, a time difference does not often occur between the time when the output voltage reaches the first reference voltage and the time when the switching of the second driver device from the on state to the off state is completed. In addition, variations in the output voltage due to disturbing noise or other factors are smaller than those in the gate-source voltages of the first and second driver devices. Thus, the time when the output voltage reaches the first reference voltage does not easily vary. For this reason, it is possible to accurately set the duration of a first dead time (which is a period from when the second driver device is switched from the on state to the off state to when the first driver device is switched from the off state to the on state). For example, the duration of the first dead time can be set at an ideal length (e.g., the minimum duration sufficient to prevent occurrence of shoot-through current).

The first drive control section may include a comparator configured to deactivate a comparison result signal when the output voltage is higher than the first reference voltage, and to activate the comparison result signal when the output voltage is lower than the first reference voltage, and a latch configured to receive a first control signal which is activated when the first switching time comes and is deactivated when the second switching time comes, to activate a first drive signal to be supplied to the first driver device in synchronization with activation of the comparison result signal when the first control signal is activated, and to deactivate the first drive signal when the first control signal is deactivated, and the first driver device may be in the on state when the first drive signal is activated, and be in the off state when the first drive signal is deactivated.

This configuration allows the inductive load to be driven such that the current-flow direction of the inductive load is in a discharge direction (i.e., a direction from the output node to the inductive load).

The first drive control section may include a comparator configured to deactivate a comparison result signal when the output voltage is lower than the first reference voltage, and to activate the comparison result signal when the output voltage is higher than the first reference voltage, and a latch configured to receive a first control signal which is activated when the first switching time comes and is deactivated when the second switching time comes, to activate a first drive signal to be supplied to the first driver device in synchronization with activation of the comparison result signal when the first control signal is activated, and to deactivate the first drive signal when the first control signal is deactivated, and the first driver device may be in the on state when the first drive signal is activated, and be in the off state when the first drive signal is deactivated.

This configuration allows the inductive load to be driven such that the current-flow direction of the inductive load is in a suction direction (i.e., a direction from the inductive load to the output node).

In a case where the first voltage is lower than the second voltage, the first drive control section may include a comparator configured to deactivate a comparison result signal when the output voltage is higher than the first reference voltage, and to activate the comparison result signal when the output voltage is lower than the first reference voltage, and a first logic circuit configured to receive a first control signal which is activated when the first switching time comes and is deactivated when the second switching time comes, to activate a first drive signal to be supplied to the first driver device when both of the first control signal and the comparison result signal are activated, and to deactivate the first drive signal when at least one of the first control signal and the comparison result signal is deactivated, and the first driver device may be in the on state when the first drive signal is activated, and be in the off state when the first drive signal is deactivated.

This configuration allows the inductive load to be driven such that the current-flow direction of the inductive load is in the discharge direction.

In a case where the first voltage is higher than the second voltage, the first drive control section may include a comparator configured to deactivate a comparison result signal when the output voltage is lower than the first reference voltage, and to activate the comparison result signal when the output voltage is higher than the first reference voltage, and a first logic circuit configured to receive a first control signal which is activated when the first switching time comes and is deactivated when the second switching time comes, to activate a first drive signal to be supplied to the first driver device when both of the first control signal and the comparison result signal are activated, and to deactivate the first drive signal when at least one of the first control signal and the comparison result signal is deactivated, and the first driver device may be in the on state when the first drive signal is activated, and be in the off state when the first drive signal is deactivated.

This configuration allows the inductive load to be driven such that the current-flow direction of the inductive load is in the suction direction.

The first drive control section may switch the first driver device from the off state to the on state after a lapse of a predetermined first delay time, after detecting that the output voltage reaches the first reference voltage, when the first switching time comes, and switch the first driver device from the on state to the off state when the second switching time comes.

This configuration provides a first delay time in a first dead time (i.e., a period from when the second driver device is switched from the on state to the off state to when the first driver device is switched from the off state to the on state). Thus, adjustment of the duration of the first delay time allows the duration of the first dead time to be adjusted.

The first drive control section may have first and second comparison modes. In this case, in the first comparison mode, the first drive control section may switch the first driver device from the off state to the on state, after detecting that the output voltage falls below a predetermined first comparison voltage, when the first switching time comes, whereas the first drive control section may switch the first driver device from the on state to the off state when the second switching time comes. In addition, in the second comparison mode, the first drive control section may switch the first driver device from the off state to the on state, after detecting that the output voltage exceeds a predetermined second comparison voltage, when the first switching time comes, whereas the first drive control section may switch the first driver device from the on state to the off state when the second switching time comes.

This configuration enables the current-flow direction of the inductive load to be set in an intended direction.

The second drive control section may switch the second driver device from the on state to the off state when the first switching time comes, whereas the second drive control section may switch the second driver device from the off state to the on state, after detecting that the output voltage reaches a predetermined second reference voltage, when the second switching time comes.

With this configuration, it is possible to accurately set not only the duration of a first dead time (i.e., a period from when the second driver device is switched from the on state to the off state to when the first driver device is switched from the off state to the on state) but also the duration of a second dead time (i.e., a period from when the first driver device is switched from the on state to the off state to when the second driver device is switched from the off state to the on state).

The load driver system may further include a first drive switch having first and second driving modes, allowing the first drive control section to control on/off of the first driver device in the first driving mode, and fixing the first driver device in one of the on state and the off state in the second driving mode and a second drive switch having third and fourth driving modes, allowing the second drive control section to control on/off of the second driver device in the third driving mode, and fixing the second driver device in one of the on state and the off state in the fourth driving mode.

This load driver system can provide not only driving with a synchronous rectification driving method but also driving with a driving method except for the synchronous rectification driving method.

### BRIEF DESCRIPTION OF THE DRAWINGS

FIG. 1 is a diagram illustrating an example of a configuration of a load driver system according to a first embodiment.

FIG. 2 is a time chart for describing operation of the load driver system illustrated in FIG. 1.

FIG. 3 is a diagram illustrating an example of a configuration of a load driver system according to a first variation of the first embodiment.

FIG. 4 is a time chart for describing operation of the load driver system illustrated in FIG. 3.

FIG. 5 is a diagram illustrating an example of a configuration of a load driver system according to a second variation of the first embodiment.

FIG. 6 is a time chart for describing operation of the load driver system illustrated in FIG. 5.

FIG. 7 is a diagram illustrating an example of a configuration of a load driver system according to a third variation of the first embodiment.

FIG. 8 is a time chart for describing operation of the load driver system illustrated in FIG. 7.

FIG. 9 is a diagram illustrating an example of a configuration of a load driver system according to a fourth variation of the first embodiment.

FIG. 10 is a time chart for describing operation of the load driver system illustrated in FIG. 9.

FIG. 11 is a diagram illustrating an example of a configuration of a load driver system according to a fifth variation of the first embodiment.

FIG. 12 is a time chart for describing operation of the load driver system illustrated in FIG. 11.

FIG. 13 is a diagram illustrating an example of a configuration of a load driver system according to a sixth variation of the first embodiment.

FIG. 14 is a time chart for describing operation of the load driver system illustrated in FIG. 13.

FIG. 15 is a diagram illustrating an example of a configuration of a load driver system according to a seventh variation of the first embodiment.

FIG. 16 is a time chart for describing operation of the load driver system illustrated in FIG. 15.

FIG. 17 is a diagram illustrating an example of a configuration of a load driver system according to an eighth variation of the first embodiment.

FIG. 18 is a time chart for describing operation of the load driver system illustrated in FIG. 17.

FIG. 19 is a diagram illustrating an example of a configuration of a load driver system according to a ninth variation of the first embodiment.

FIG. 20 is a time chart for describing operation of the load driver system illustrated in FIG. 19.

FIG. 21 is a diagram illustrating an example of a configuration of a load driver system according to a second embodiment.

FIGS. 22A and 22B are examples of diagrams illustrated in FIG. 21.

FIG. 23 is a time chart for describing operation of the load driver system illustrated in FIG. 21.

FIG. 24 is a diagram illustrating an example of a configuration of a load driver system according to a third embodiment.

FIG. 25 is a diagram illustrating another example of the configuration of the load driver system according to the third embodiment.

FIG. 26 is a diagram illustrating an example of a configuration of a load driver system according to a fourth embodiment.

### DETAILED DESCRIPTION

Embodiments of the present disclosure will be described in detail hereinafter with reference to the drawings. In the drawings, like reference characters are used to designate identical or equivalent elements, and explanation thereof is not repeated.

### First Embodiment

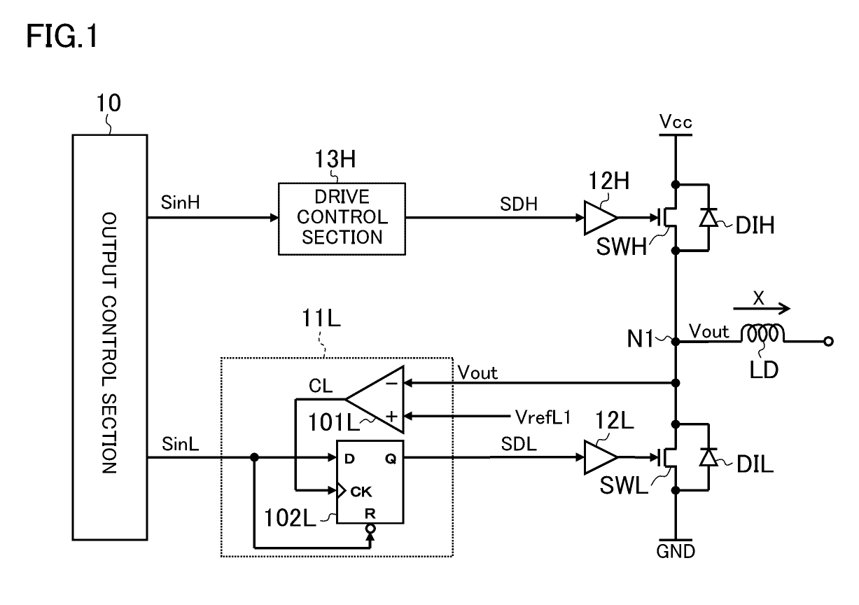

FIG. 1 illustrates an example of a configuration of a load driver system according to a first embodiment. The load driver system is configured to drive an inductive load LD, and includes: a low-side driver device SWL; a low-side freewheeling diode DIL; a high-side driver device SWH; a high-side freewheeling diode DIH; an output control section 10; a low-side drive control section 11L; a low-side pre-driver 12L; a high-side drive control section 13H; and a high-side pre-driver 12H. In FIG. 1, the load driver system drives the inductive load LD such that the current-flow direction of the inductive load LD is in a discharge direction X (i.e., the direction from an output node N1 toward the inductive load LD).

### [Driver Device and Freewheeling Diode]

The low-side driver device SWL and the low-side freewheeling diode DIL are connected in parallel between the output node N1 and a ground node. The output node N1 is connected to the inductive load LD. The ground node receives a ground voltage GND. The high-side driver device SWH and the high-side freewheeling diode DIH are connected in parallel between the output node N1 and a power supply node. The power supply node receives a power supply voltage Vcc.

### [Output Control Section]

The output control section 10 outputs a low-side control signal SinL and a high-side control signal SinH for determining a switching time of turning on/off the low-side driver device SWL and the high-side driver device SWH, respectively. For example, the output control section 10 repeatedly and alternately performs operation of changing the signal level of the low-side control signal SinL from a high level to a low level and the signal level of the high-side control signal SinH from a low level to a high level and operation of changing the signal level of the low-side control signal SinL from the low level to the high level and the signal level of the high-side control signal SinH from the high level to the low level.

### [Low-side Drive Control Section]

When a first switching time comes (which is, in this embodiment, when the signal level of the low-side control signal SinL changes from the low level to the high level), the low-side drive control section 11L detects that an output voltage Vout at the output node N1 reaches a predetermined reference voltage VrefL1, and then changes the signal level of the low-side drive signal SDL from the low level to the high level, thereby switching the low-side driver device SWL from the off state to the on state. Then, when a second switching time comes (which is, in this embodiment, when the signal level of the low-side control signal SinL changes from the high level to the low level), the low-side drive control section 11L changes the signal level of the low-side drive signal SDL from the high level to the low level, thereby switching the low-side driver device SWL from the on state to the off state.

The low-side drive control section 11L includes a comparator 101L and a flip-flop (a latch) 102L, for example. In this embodiment, the comparator 101L changes the signal level of a comparison result signal CL to a low level when the output voltage Vout is higher than the reference voltage VrefL1, and changes the signal level of the comparison result signal CL to a high level when the output voltage Vout is lower than the reference voltage VrefL1. When the signal level of the low-side control signal SinL is at the high level, the flip-flop 102L changes the signal level of the low-side drive signal SDL from the low level to the high level in synchronization with the change of the comparison result signal CL from the low level to the high level. When the signal level of the low-side control signal SinL changes from the high level to the low level, the flip-flop 102L changes the signal level of the low-side drive signal SDL from the high level to the low level.

### [Low-Side Pre-Driver]

The low-side pre-driver 12L amplifies the low-side drive signal SDL from the low-side drive control section 11L, and supplies the amplified low-side drive signal SDL to the low-side driver device SWL. The low-side driver device SWL is turned on when the signal level of the low-side drive signal SDL is at the high level, and is turned off when the signal level of the low-side drive signal SDL is at the low level.

### [High-Side Drive Control Section]

When a first switching time comes (which is, in this embodiment, when the signal level of the high-side control signal SinH changes from the high level to the low level), the high-side drive control section 13H changes the signal level of the high-side drive signal SDH from the high level to the low level, thereby switching the high-side driver device SWH from the on state to the off state. Then, when a second switching time comes (which is, in this embodiment, when the signal level of the high-side control signal SinH changes from the low level to the high level), the high-side drive control section 13H changes the signal level of the high-side drive signal SDH from the low level to the high level, thereby switching the high-side driver device SWH from the off state to the on state.

For example, when the signal level of the high-side control signal SinH changes from the low level to the high level, the high-side drive control section 13H may change the signal level of the high-side drive signal SDH from the low level to the high level after a lapse of a predetermined delay time. Alternatively, when the signal level of the high-side control signal SinH changes from the low level to the high level, the high-side drive control section 13H may change the signal level of the high-side drive signal SDH from the low level to the high level after detecting that the gate-source voltage of the low-side driver device SWL falls below a predetermined reference voltage (e.g., a voltage equal to, or lower than, the threshold voltage of the low-side driver device SWL).

### [High-Side Pre-Driver]

The high-side pre-driver 12H amplifies the high-side drive signal SDH from the high-side drive control section 13H, and supplies the amplified high-side drive signal SDH to the high-side driver device SWH. The high-side driver device SWH is turned on when the signal level of the high-side drive signal SDH is at the high level, and is turned off when the signal level of the high-side drive signal SDH is at the low level.

### [Reference Voltage Range]

For simplicity of description, some components will be hereinafter designated by characters as follows:
power supply voltage Vcc: Vcc
current flowing in inductive load LD: I
ON resistance of low-side driver device SWL: RL
ON resistance of high-side driver device SWH: RH
voltage of low-side freewheeling diode DIL: VDIL
voltage of high-side freewheeling diode DIH: VDIH

The reference voltage VrefL1 is set as:

−VDIL<VrefL1<Vcc−RH×I

### [Operation]

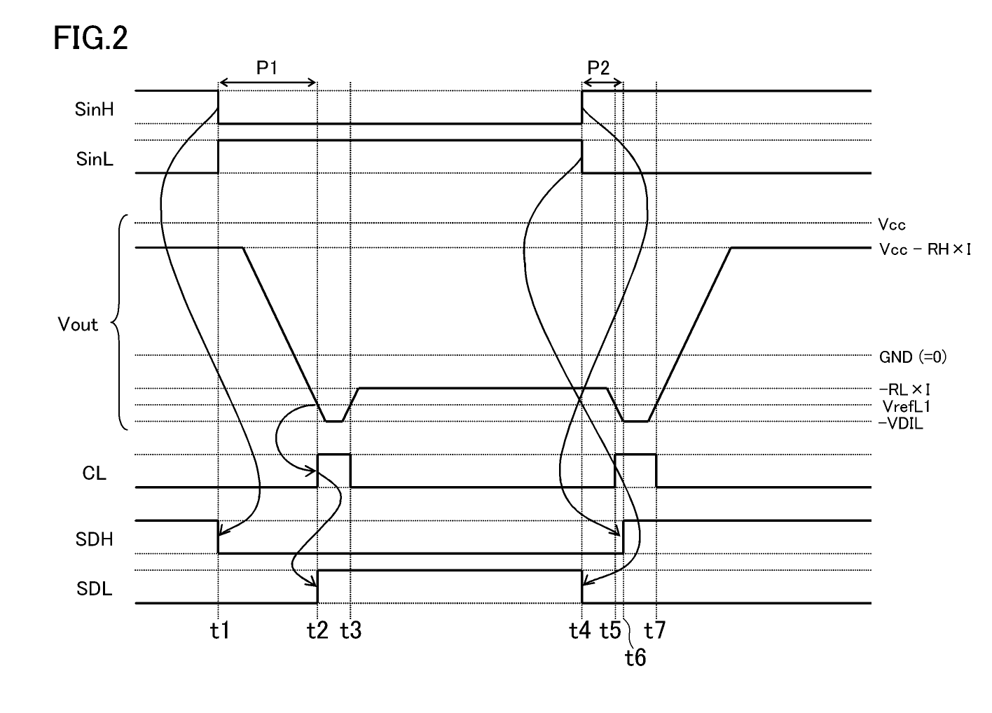

Referring now to FIG. 2, operation of the load driver system illustrated in FIG. 1 will be described. In this embodiment, when the signal level of the high-side control signal SinH changes from the low level to the high level, the high-side drive control section 13H changes the signal level of the high-side drive signal SDH from the low level to the high level after a lapse of delay time P2.

At time t1 (i.e., the first switching time), the high-side drive control section 13H changes the signal level of the high-side drive signal SDH from the high level to the low level in response to the change of the high-side control signal SinH from the high level to the low level. Accordingly, the high-side driver device SWH switches from the on state to the off state. When the switching of the high-side driver device SWH from the on state to the off state is completed, the current path to the inductive load LD switches from “the power supply node (Vcc)→the high-side driver device SWH→the inductive load LD” to “the ground node (GND)→the low-side freewheeling diode DIL→the inductive load LD,” and the output voltage Vout starts changing toward “−VDIL.”

Then, at time t2, the output voltage Vout falls below the reference voltage VrefL1. Accordingly, the comparator 101L changes the signal level of the comparison result signal CL from the low level to the high level. Since the signal level of the low-side control signal SinL is the high level, the flip-flop 102L changes the signal level of the low-side drive signal SDL from the low level to the high level in response to the change of the comparison result signal CL from the low level to the high level. This change causes the low-side driver device SWL to switch from the off state to the on state. When the switching of the low-side driver device SWL from the off state to the on state is completed, the current path to the inductive load LD switches from “the ground node (GND)→the low-side freewheeling diode DIL→the inductive load LD” to “the ground node (GND)→the low-side driver device SWL→the inductive load LD,” and the output voltage Vout starts changing toward “−RL×I.”

Thereafter, at time t3, the output voltage Vout exceeds the reference voltage VrefL1. At this time, the flip-flop 102L does not respond to a change of the comparison result signal CL from the high level to the low level, and keeps the signal level of the low-side drive signal SDL at the high level. Accordingly, the low-side driver device SWL is kept in the on state.

Subsequently, at time t4 (i.e., the second switching time), the flip-flop 102L changes the signal level of the low-side drive signal SDL from the high level to the low level, in response to a change of the low-side control signal SinL from the high level to the low level. Accordingly, the low-side driver device SWL switches from the on state to the off state. When the switching of the low-side driver device SWL from the on state to the off state is completed, the current path to the inductive load LD switches from “the ground node (GND)→the low-side driver device SWL→the inductive load LD” to “the ground node (GND)→the low-side freewheeling diode DIL→the inductive load LD,” and the output voltage Vout starts changing toward “−VDIL.”

Then, at time t5, the output voltage Vout falls below the reference voltage VrefL1, and the signal level of the comparison result signal CL changes from the low level to the high level. At this time, since the signal level of the low-side control signal SinL is at the low level, the flip-flop 102L does not respond to the change of the comparison result signal CL from the low level to the high level, and keeps the signal level of the low-side drive signal SDL at the low level. Accordingly, the low-side driver device SWL is kept in the off state.

Subsequently, at time t6 (i.e., after a lapse of delay time P2 from time t4), the high-side drive control section 13H changes the signal level of the high-side drive signal SDH from the low level to the high level. Accordingly, the high-side driver device SWH switches from the off state to the on state. When the switching of the high-side driver device SWH from the off state to the on state is completed, the current path to the inductive load LD switches from “the ground node (GND)→the low-side freewheeling diode DIL the inductive load LD” to “the power supply node (Vcc)→the high-side driver device SWH→the inductive load LD,” and the output voltage Vout starts changing toward “Vcc−RH×I.”

Then, at time t7, the output voltage Vout exceeds the reference voltage VrefL1, and the comparator 101L changes the signal level of the comparison result signal CL from the high level to the low level. At this time, the flip-flop 102L does not respond to the change of the comparison result signal CL from the high level to the low level, and keeps the signal level of the low-side drive signal SDL at the low level. Accordingly, the low-side driver device SWL is kept in the off state.

In the manner described above, the output voltage Vout varies depending on on/off of the low-side driver device SWL and the high-side driver device SWH. Accordingly, even when the threshold voltages of the low-side driver device SWL and the high-side driver device SWH vary, a time difference does not easily occur between the time when the output voltage Vout reaches the reference voltage VrefL1 and the time when the switching of the high-side driver device SWH from the on state to the off state is completed. In addition, variations in the output voltage Vout due to disturbing noise or other factors are smaller than those in the gate-source voltages of the low-side driver device SWL and the high-side driver device SWH. Thus, the time when the output voltage Vout reaches the reference voltage VrefL1 does not easily vary. For this reason, it is possible to accurately set the duration of the dead time (which is, in this embodiment, period P1 from when the high-side driver device SWH is switched from the on state to the off state to when the low-side driver device SWL is switched from the off state to the on state). For example, the duration of the dead time (i.e., period P1) can be set at an ideal length (e.g., the minimum duration sufficient to prevent occurrence of shoot-through current).

### (First Variation of First Embodiment)

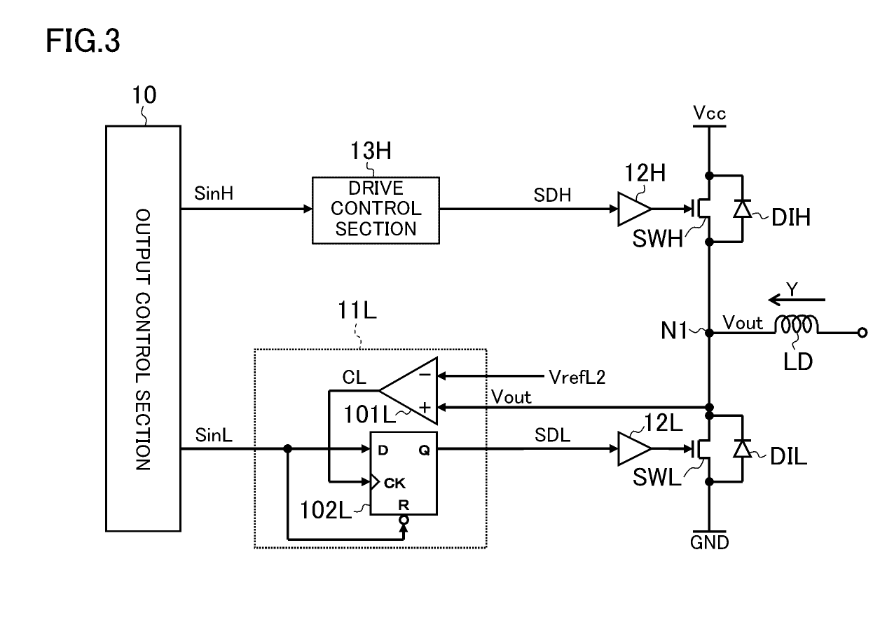

As illustrated in FIG. 3, in driving the inductive load LD such that the current-flow direction of the inductive load LD is in a suction direction Y (i.e., the direction from the inductive load LD to the output node N1), the comparator 101L may set the signal level of the comparison result signal CL at the low level when the output voltage Vout is lower than a predetermined reference voltage VrefL2, and set the signal level of the comparison result signal CL at the high level when the output voltage Vout is higher than the reference voltage VrefL2.

### [Reference Voltage Range]

The reference voltage VrefL2 is set as:

Vcc+RH×I<VrefL2<Vcc+VDIH

### [Operation]

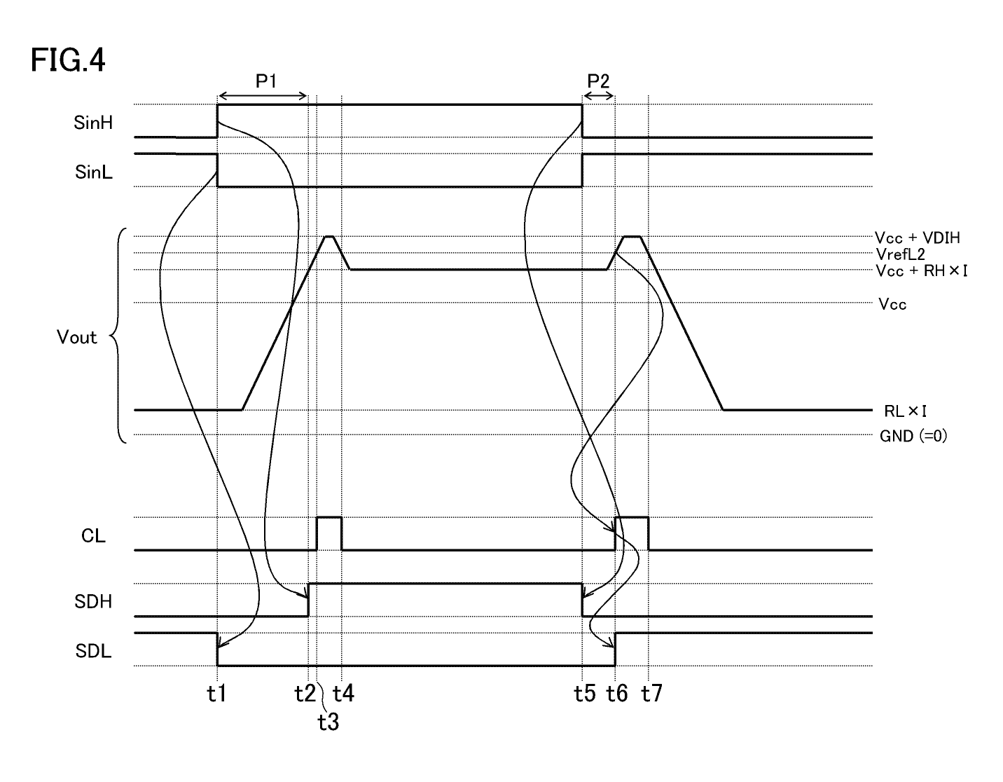

Referring now to FIG. 4, operation of the load driver system illustrated in FIG. 3 will be described. In this variation, when the signal level of the high-side control signal SinH changes from the low level to the high level, the high-side drive control section 13H changes the signal level of the high-side drive signal SDH from the low level to the high level after a lapse of delay time P1.

At time t1 (i.e., the second switching time), the flip-flop 102L changes the signal level of the low-side drive signal SDL from the high level to the low level in response to a change of the low-side control signal SinL from the high level to the low level. Accordingly, the low-side driver device SWL switches from the on state to the off state. When the switching of the low-side driver device SWL from the on state to the off state is completed, the current path from the inductive load LD switches from “the inductive load LD→the low-side driver device SWL→the ground node (GND)” to “the inductive load LD→the high-side freewheeling diode DIH→the power supply node (Vcc),” and the output voltage Vout starts changing toward “Vcc+VDIH.”

Then, at time t2 (i.e., after a lapse of delay time P1 from time t1), the high-side drive control section 13H changes the signal level of the high-side drive signal SDH from the low level to the high level. Accordingly, the high-side driver device SWH switches from the off state to the on state. When the switching of the high-side driver device SWH from the off state to the on state is completed, the current path from the inductive load LD switches from “the inductive load LD→the high-side freewheeling diode DIH→the power supply node (Vcc)” to “the inductive load LD→the high-side driver device SWH→the power supply node (Vcc),” and the output voltage Vout starts changing toward “Vcc+RH×I.”

Thereafter, in a period from time t3 to time t4, the output voltage Vout exceeds the reference voltage VrefL2, and the signal level of the comparison result signal CL changes to the high level. In this period, since the signal level of the low-side control signal SinL is at the low level, the flip-flop 102L keeps the signal level of the low-side drive signal SDL at the low level. Accordingly, the low-side driver device SWL is kept in the off state.

Then, at time t5 (i.e., the first switching time), in response to a change of the high-side control signal SinH from the high level to the low level, the high-side drive control section 13H changes the signal level of the high-side drive signal SDH from the high level to the low level. Accordingly, the high-side driver device SWH switches from the on state to the off state. When the switching of the high-side driver device SWH from the on state to the off state is completed, the current path from the inductive load LD switches from “the inductive load LD→the high-side driver device SWH→the power supply node (Vcc)” to “the inductive load LD→the high-side freewheeling diode DIH→the power supply node (Vcc),” and the output voltage Vout starts changing toward “Vcc+VDIH.”

Subsequently, at time t6, the output voltage Vout exceeds the reference voltage VrefL2. Accordingly, the comparator 101L changes the signal level of the comparison result signal CL from the low level to the high level. In response to the change of the comparison result signal CL from the low level to the high level, the flip-flop 102L changes the signal level of the low-side drive signal SDL from the low level to the high level. Accordingly, the low-side driver device SWL switches from the off state to the on state. When the switching of the low-side driver device SWL from the off state to the on state is completed, the current path from the inductive load LD switches from “the inductive load LD→the high-side freewheeling diode DIH→the power supply node (Vcc)” to “the inductive load LD→the low-side driver device SWL→the ground node (GND),” and the output voltage Vout starts changing toward “RL×I.”

Then, at time t7, the output voltage Vout falls below the reference voltage VrefL2, and the signal level of the comparison result signal CL changes from the high level to the low level. At this time, the flip-flop 102L does not respond to the change of the comparison result signal CL from the high level to the low level, and keeps the signal level of the low-side drive signal SDL at the high level. Accordingly, the low-side driver device SWL is kept in the on state.

In the configuration described above, it is also possible to accurately set the duration of the dead time (which is, in this variation, period P2 from when the high-side driver device SWH is switched from the on state to the off state to when the low-side driver device SWL is switched from the off state to the on state).

### (Second Variation of First Embodiment)

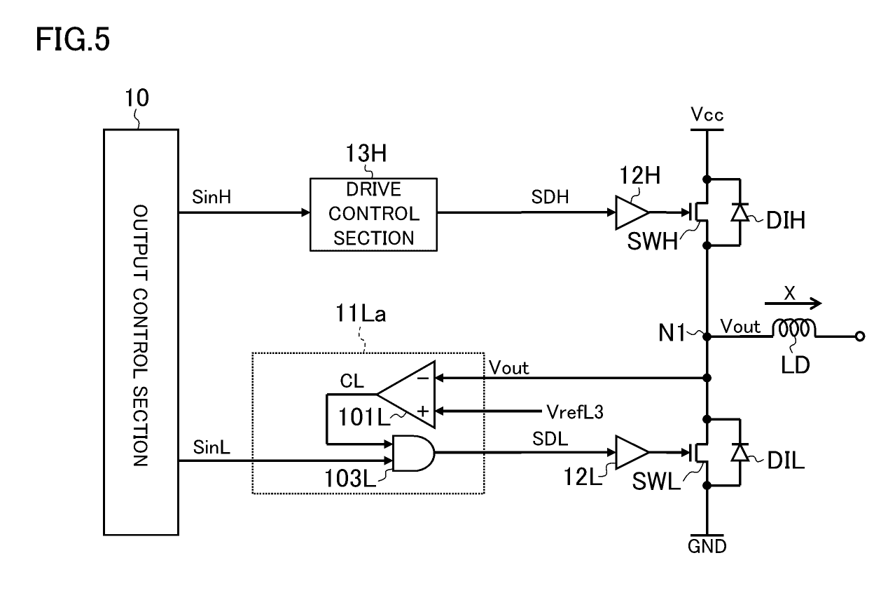

As illustrated in FIG. 5, the load driver system may include a low-side drive control section 11La, instead of the low-side drive control section 11L illustrated in FIG. 1. Other part of the configuration is the same as in the load driver system illustrated in FIG. 1.

In FIG. 5, the load driver system drives the inductive load LD such that the current-flow direction of the inductive load LD is in the discharge direction X.

### [Low-Side Drive Control Section]

The low-side drive control section 11La includes a comparator 101L and an AND circuit (a logic circuit) 103L. In this variation, the comparator 101L sets the signal level of the comparison result signal CL at the low level when the output voltage Vout is higher than a predetermined reference voltage VrefL3, and sets the signal level of the comparison result signal CL at the high level when the output voltage Vout is lower than the reference voltage VrefL3. The AND circuit 103L sets the signal level of the low-side drive signal SDL at the high level when the signal levels of both of the low-side control signal SinL and the comparison result signal CL are at the high level, and sets the signal level of the low-side drive signal SDL at the low level when the signal level of at least one of the low-side control signal SinL and the comparison result signal CL is at the low level.

### [Reference Voltage Range]

The reference voltage VrefL3 is set as:

RL×I<VrefL3<Vcc−RH×I

### [Operation]

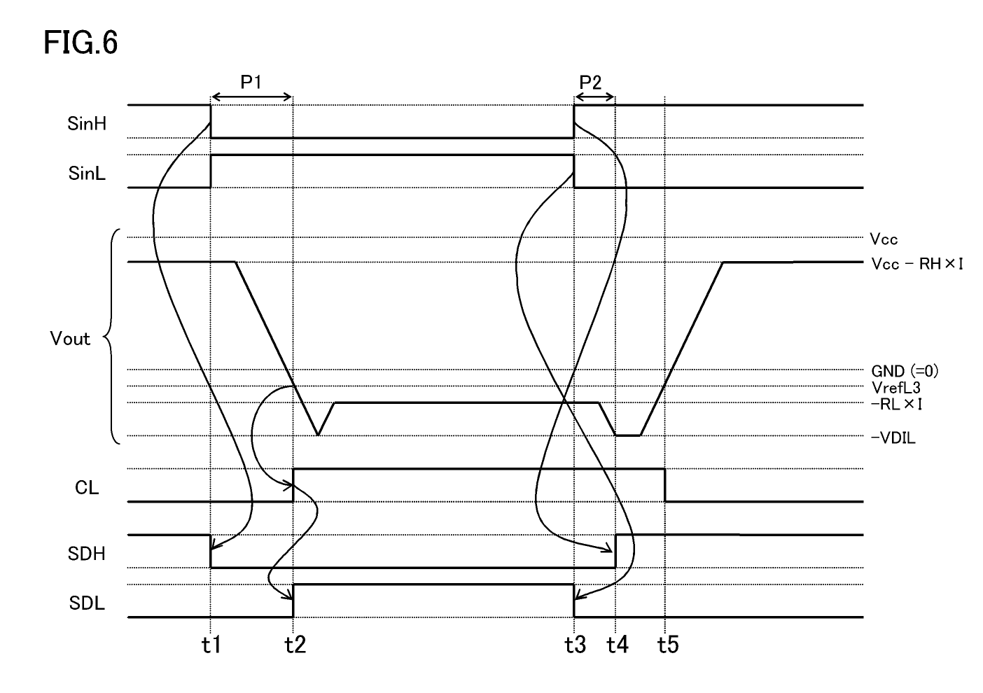

Referring now to FIG. 6, operation of the load driver system illustrated in FIG. 5 will be described. In this variation, when the signal level of the high-side control signal SinH changes from the low level to the high level, the high-side drive control section 13H changes the signal level of the high-side drive signal SDH from the low level to the high level after a lapse of delay time P2.

At time t1 (i.e., the first switching time), the high-side drive control section 13H changes the signal level of the high-side drive signal SDH from the high level to the low level in response to a change of the high-side control signal SinH from the high level to the low level.

Then, at time t2, the output voltage Vout falls below the reference voltage VrefL3, and the signal level of the comparison result signal CL changes from the low level to the high level. In response to the change of the comparison result signal CL from the low level to the high level, the AND circuit 103L changes the signal level of the low-side drive signal SDL from the low level to the high level.

Thereafter, at time t3 (i.e., the second switching time), in response to a change of the low-side control signal SinL from the high level to the low level, the AND circuit 103L changes the signal level of the low-side drive signal SDL from the high level to the low level.

Subsequently, at time t4 (i.e., after a lapse of delay time P2 from time t3), the high-side drive control section 13H changes the signal level of the high-side drive signal SDH from the low level to the high level.

Then, at time t5, the output voltage Vout exceeds the reference voltage VrefL3, and the comparator 101L changes the signal level of the comparison result signal CL from the high level to the low level. At this time, since the signal level of the low-side control signal SinL is already at the low level, the AND circuit 103L keeps the signal level of the low-side drive signal SDL at the low level.

In the configuration described above, it is also possible to accurately set the duration of the dead time (which is, in this variation, period P1 from when the high-side driver device SWH is switched from the on state to the off state to when the low-side driver device SWL is switched from the off state to the on state).

### (Third Variation of First Embodiment)

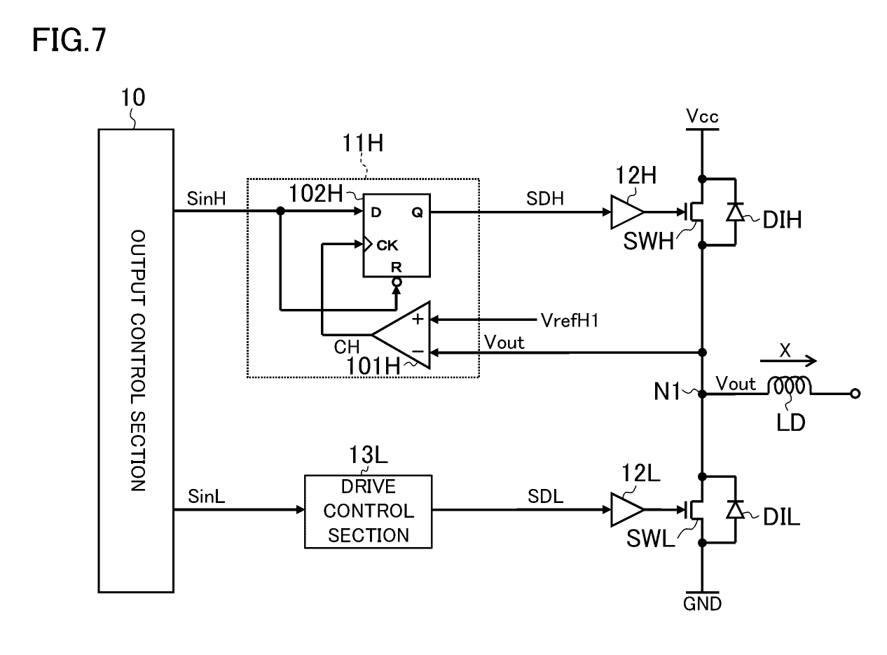

As illustrated in FIG. 7, the load driver system may include a low-side drive control section 13L and a high-side drive control section 11H, instead of the low-side drive control section 11L and the high-side drive control section 13H illustrated in FIG. 1. Other part of the configuration is the same as in the load driver system illustrated in FIG. 1. In FIG. 7, the load driver system drives the inductive load LD such that the current-flow direction of the inductive load LD is in the discharge direction X.

### [Low-side Drive Control Section]

When a first switching time comes (which is, in this variation, when the signal level of the low-side control signal SinL changes from the high level to the low level), the low-side drive control section 13L changes the signal level of the high-side drive signal SDH from the high level to the low level, thereby switching the low-side driver device SWL from the on state to the off state. When a second switching time comes (which is, in this variation, when the signal level of the low-side control signal SinL changes from the low level to the high level), the low-side drive control section 13L changes the signal level of the low-side drive signal SDL from the low level to the high level, thereby switching the low-side driver device SWL from the off state to the on state.

For example, when the signal level of the low-side control signal SinL changes from the low level to the high level, the low-side drive control section 13L may change the signal level of the low-side drive signal SDL from the low level to the high level after a lapse of a predetermined delay time. Alternatively, when the signal level of the low-side control signal SinL changes from the low level to the high level, the low-side drive control section 13L may change the signal level of the low-side drive signal SDL from the low level to the high level after detecting that the gate-source voltage of the high-side driver device SWH falls below a predetermined reference voltage (e.g., a voltage equal to, or lower than, the threshold voltage of the high-side driver device SWH).

### [High-side Drive Control Section]

When a first switching time comes (which is, in this variation, when the signal level of the high-side control signal SinH changes from the low level to the high level), the high-side drive control section 11H detects that the output voltage Vout reaches a predetermined reference voltage VrefH1, and then changes the signal level of the high-side drive signal SDH from the low level to the high level, thereby switching the high-side driver device SWH from the off state to the on state. When a second switching time comes (which is, in this variation, when the signal level of the high-side control signal SinH changes from the high level to the low level), the high-side drive control section 11H changes the signal level of the high-side drive signal SDH from the high level to the low level, thereby switching the high-side driver device SWH from the on state to the off state. The high-side drive control section 11H includes a comparator 101H and a flip-flop (a latch) 102H, for example. The comparator 101H sets the signal level of the comparison result signal CH at the low level when the output voltage Vout is higher than the reference voltage VrefH1, and sets the signal level of the comparison result signal CH at the high level when the output voltage Vout is lower than the reference voltage VrefH1. When the signal level of the high-side control signal SinH is at the high level, the flip-flop 102H changes the signal level of the high-side drive signal SDH from the low level to the high level in synchronization with the change in the signal level of the comparison result signal CH from the low level to the high level. When the signal level of the high-side control signal SinH from the high level to the low level, the flip-flop 102H changes the signal level of the high-side drive signal SDH from the high level to the low level.

### [Reference Voltage Range]

The reference voltage VrefH1 is set as:

−VDIL<VrefH1<−RL×I

### [Operation]

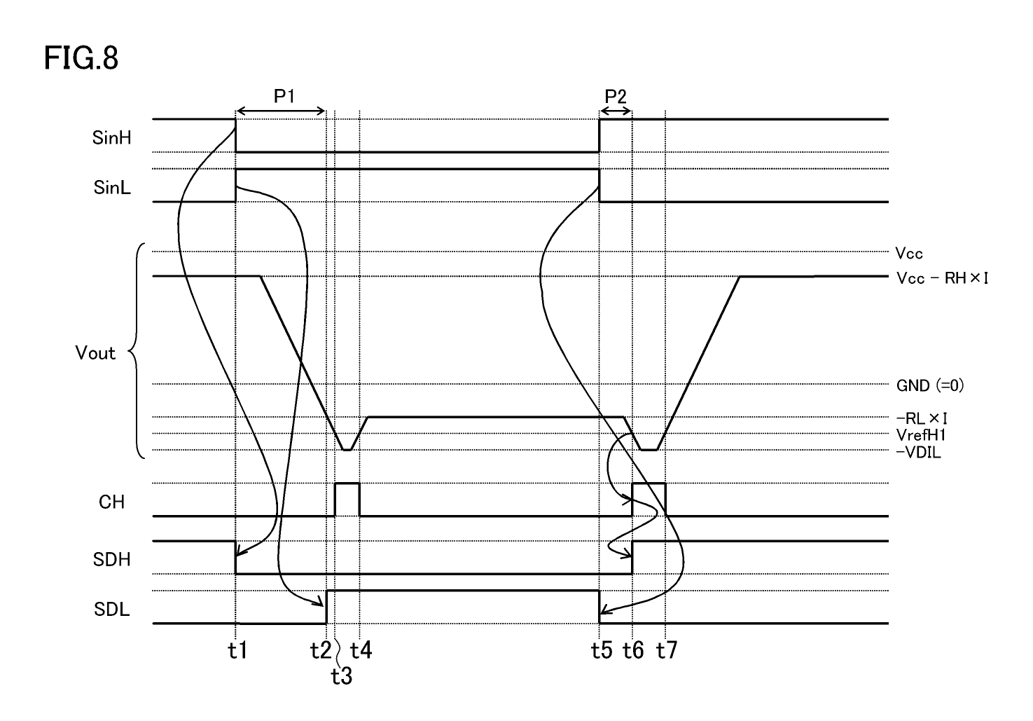

Referring now to FIG. 8, operation of the load driver system illustrated in FIG. 7 will be described. In this variation, when the signal level of the low-side control signal SinL changes from the low level to the high level, the low-side drive control section 13L changes the signal level of the low-side drive signal SDL from the low level to the high level after a lapse of delay time P1.

At time t1 (i.e., the second switching time), the flip-flop 102H changes the signal level of the high-side drive signal SDH from the high level to the low level in response to a change of the high-side control signal SinH from the high level to the low level.

Then, at time t2 (i.e., after a lapse of delay time P1 from time t1), the low-side drive control section 13L changes the signal level of the low-side drive signal SDL from the low level to the high level.

Thereafter, in a period from time t3 to time t4, the output voltage Vout falls below the reference voltage VrefH1, and the signal level of the comparison result signal CH changes to the high level. In this period, since the signal level of the high-side control signal SinH is at the low level, the flip-flop 102H keeps the signal level of the high-side drive signal SDH at the low level.

Then, at time t5 (i.e., the first switching time), in response to a change of the low-side control signal SinL from the high level to the low level, the low-side drive control section 11L changes the signal level of the low-side drive signal SDL from the high level to the low level.

Subsequently, at time t6, the output voltage Vout falls below the reference voltage VrefH1. Accordingly, the comparator 101H changes the signal level of the comparison result signal CH from the low level to the high level. Since the signal level of the high-side control signal SinH is at the high level, the flip-flop 102H changes the signal level of the high-side drive signal SDH from the low level to the high level in response to the change of the comparison result signal CH from the low level to the high level.

Then, at time t7, the output voltage Vout exceeds the reference voltage VrefH1, and the signal level of the comparison result signal CH changes from the high level to the low level. At this time, the flip-flop 102H does not respond to the change of the comparison result signal CH from the high level to the low level, and keeps the signal level of the high-side drive signal SDH at the high level.

In the configuration described above, it is also possible to accurately set the duration of the dead time (which is, in this variation, period P2 from when the low-side driver device SWL is switched from the on state to the off state to when the high-side driver device SWH is switched from the off state to the on state).

### (Fourth Variation of First Embodiment)

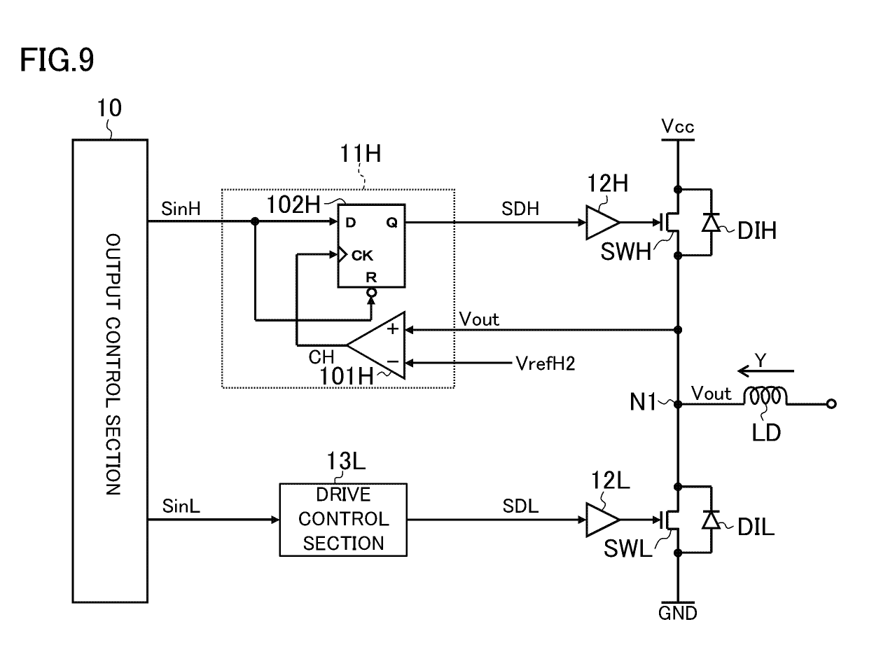

As illustrated in FIG. 9, in driving the inductive load LD such that the current-flow direction of the inductive load LD is in the suction direction Y, the comparator 101H may set the signal level of the comparison result signal CH at the low level when the output voltage Vout is lower than a predetermined reference voltage VrefH2, and set the signal level of the comparison result signal CH at the high level when the output voltage Vout is higher than the reference voltage VrefH2.

### [Reference Voltage Range]

The reference voltage VrefH2 is set as:

RL×I<VrefH2<Vcc+VDIH

### [Operation]

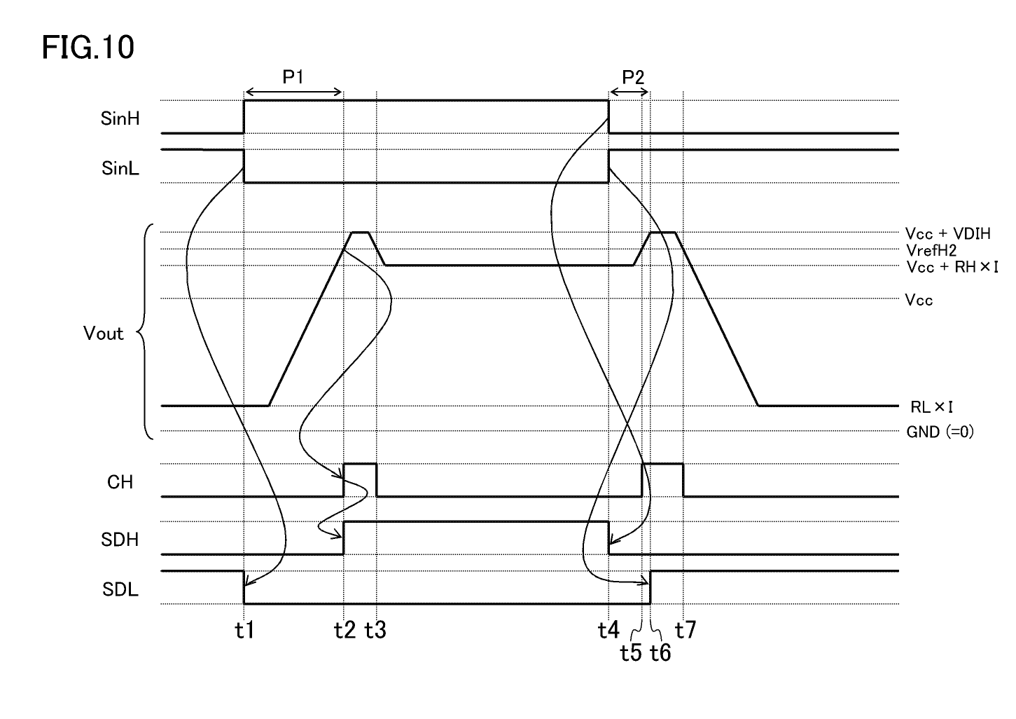

Referring now to FIG. 10, operation of the load driver system illustrated in FIG. 9 will be described. In this variation, when the signal level of the low-side control signal SinL changes from the low level to the high level, the low-side drive control section 13L changes the signal level of the low-side drive signal SDL from the low level to the high level after a lapse of delay time P2.

At time t1 (i.e., the first switching time), the low-side drive control section 13L changes the signal level of the low-side drive signal SDL from the high level to the low level in response to a change of the low-side control signal SinL from the high level to the low level.

Then, at time t2, the output voltage Vout exceeds the reference voltage VrefH2, and the signal level of the comparison result signal CH changes from the low level to the high level. In response to the change of the comparison result signal CH from the low level to the high level, the flip-flop 102H changes the signal level of the high-side drive signal SDH from the low level to the high level.

Thereafter, at time t3, the output voltage Vout falls below the reference voltage VrefH2, and the signal level of the comparison result signal CH changes from the high level to the low level. At this time, the flip-flop 102H does not respond to the change of the comparison result signal CH from the high level to the low level, and keeps the signal level of the high-side drive signal SDH at the high level.

Subsequently, at time t4 (i.e., the second switching time), the flip-flop 102H changes the signal level of the high-side drive signal SDH from the high level to the low level in response to the change of the high-side control signal SinH from the high level to the low level.

Then, at time t5, the output voltage Vout exceeds the reference voltage VrefH2, and the signal level of the comparison result signal CH changes from the low level to the high level. At this time, since the signal level of the high-side control signal SinH is at the low level, the flip-flop 102H does not respond to the change of the comparison result signal CH from the low level to the high level, and keeps the signal level of the high-side drive signal SDH at the low level.

Subsequently, at time t6 (i.e., after a lapse of delay time P2 from time t4), the low-side drive control section 13L changes the signal level of the low-side drive signal SDL from the low level to the high level.

Then, at time t7, the output voltage Vout falls below the reference voltage VrefH2, and the signal level of the comparison result signal CH changes from the high level to the low level. At this time, the flip-flop 102H does not respond to the change of the comparison result signal CH from the high level to the low level, and keeps the signal level of the high-side drive signal SDH at the low level.

In the configuration described above, it is also possible to accurately set the duration of the dead time (which is, in this variation, period P1 from when the low-side driver device SWL is switched from the on state to the off state to when the high-side driver device SWH is switched from the off state to the on state).

### (Fifth Variation of First Embodiment)

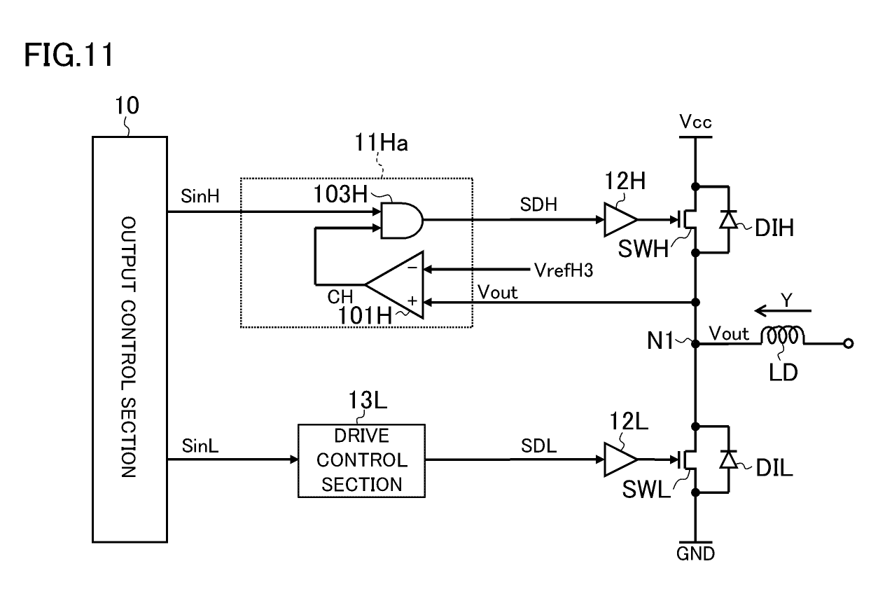

As illustrated in FIG. 11, the load driver system may include a high-side drive control section 11Ha, instead of the high-side drive control section 11H illustrated in FIG. 7. Other part of the configuration is the same as in the load driver system illustrated in FIG. 7. In FIG. 11, the load driver system drives the inductive load LD such that the current-flow direction of the inductive load LD is in the suction direction Y.

### [High-Side Drive Control Section]

The high-side drive control section 11Ha includes a comparator 101H and an AND circuit (a logic circuit) 103H. In this variation, the comparator 101H sets the signal level of the comparison result signal CH at the low level when the output voltage Vout is lower than a predetermined reference voltage VrefH3, and sets the signal level of the comparison result signal CH at the high level when the output voltage Vout is higher than the reference voltage VrefH3. The AND circuit 103H sets the signal level of the high-side drive signal SDH at the high level when the signal levels of both of the high-side control signal SinH and the comparison result signal CH are at the high level, and sets the signal level of the high-side drive signal SDH at the low level when the signal level of at least one of the high-side control signal SinH and the comparison result signal CH is at the low level.

### [Reference Voltage Range]

The reference voltage VrefH3 is set as:

RL×I<VrefH3<Vcc+RH×I

### [Operation]

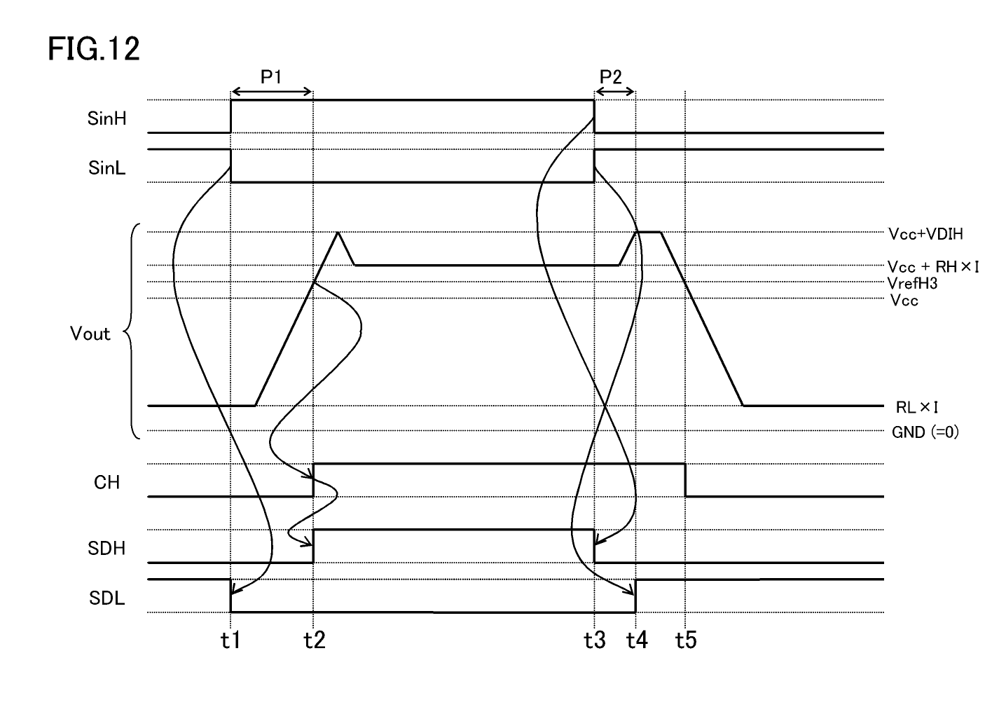

Referring now to FIG. 12, operation of the load driver system illustrated in FIG. 11 will be described. In this variation, when the signal level of the low-side control signal SinL changes from the low level to the high level, the low-side drive control section 13L changes the signal level of the low-side drive signal SDL from the low level to the high level after a lapse of delay time P2.

At time t1 (i.e., the first switching time), the low-side drive control section 13L changes the signal level of the low-side drive signal SDL from the high level to the low level in response to the change of the low-side control signal SinL from the high level to the low level.

Then, at time t2, the output voltage Vout exceeds the reference voltage VrefH3. Accordingly, the comparator 101H changes the signal level of the comparison result signal CH from the low level to the high level. In response to the change of the comparison result signal CH from the low level to the high level, the AND circuit 103H changes the signal level of the high-side drive signal SDH from the low level to the high level.

Thereafter, at time t3 (i.e., the second switching time), in response to a change of the high-side control signal SinH from the high level to the low level, the AND circuit 103H changes the signal level of the high-side drive signal SDH from the high level to the low level.

Subsequently, at time t4 (i.e., after a lapse of delay time P2 from time t3), the low-side drive control section 13L changes the signal level of the low-side drive signal SDL from the low level to the high level.

Then, at time t5, the output voltage Vout falls below the reference voltage VrefH3, and the signal level of the comparison result signal CH changes from the high level to the low level. At this time, since the signal level of the high-side control signal SinH is already at the low level, the AND circuit 103H keeps the signal level of the high-side drive signal SDH at the low level.

In the configuration described above, it is also possible to accurately set the duration of the dead time (which is, in this variation, period P1 from when the low-side driver device SWL is switched from the on state to the off state to when the high-side driver device SWH is switched from the off state to the on state).

### (Sixth Variation of First Embodiment)

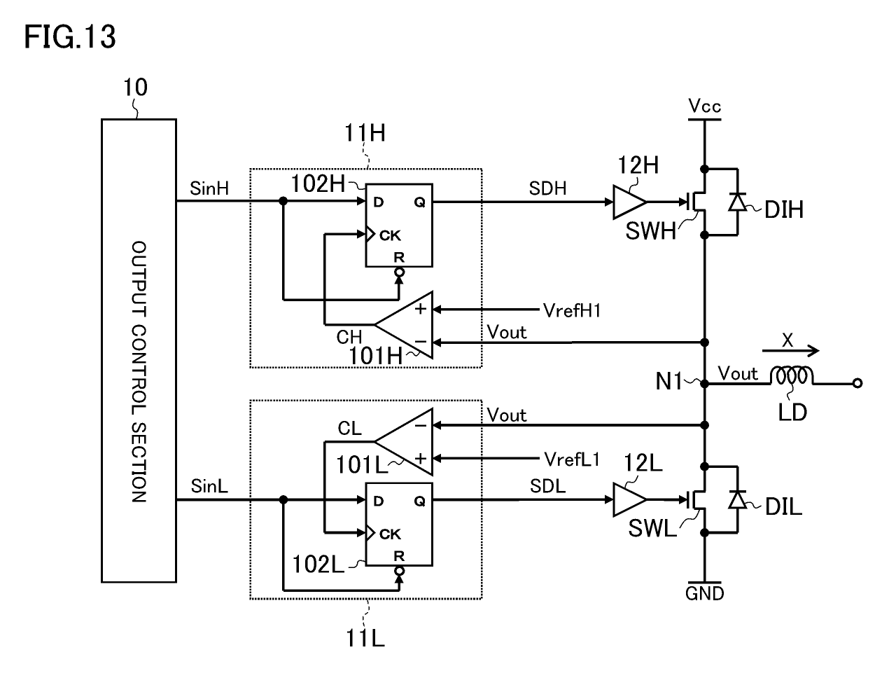

As illustrated in FIG. 13, the load driver system may include the high-side drive control section 11H illustrated in FIG. 7, instead of the high-side drive control section 13H illustrated in FIG. 1. Other part of the configuration is the same as in the load driver system illustrated in FIG. 1. In FIG. 13, the load driver system drives the inductive load LD such that the current-flow direction of the inductive load LD is in the discharge direction X.

### [Operation]

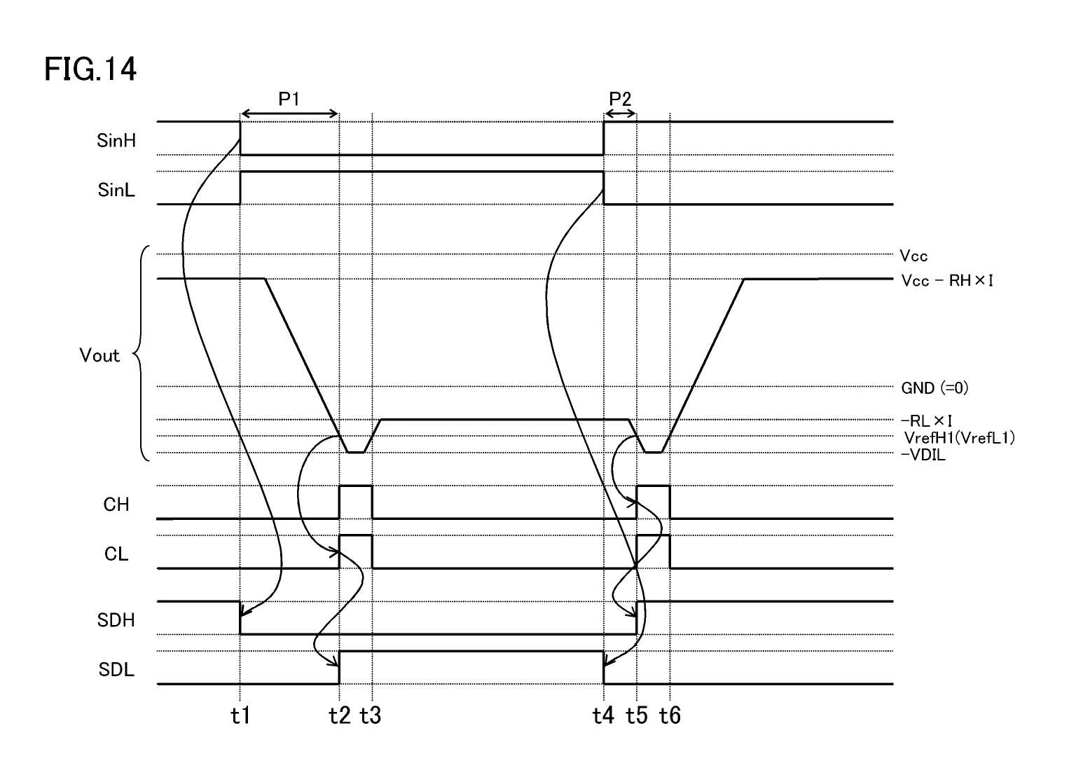

Referring now to FIG. 14, operation of the load driver system illustrated in FIG. 13 will be described. In this variation, it is assumed that the reference voltages VrefL1 and VrefH1 are the same voltage.

At time t1, in the high-side drive control section 11H, the flip-flop 102H changes the signal level of the high-side drive signal SDH from the high level to the low level in response to a change of the high-side control signal SinH from the high level to the low level. Accordingly, the high-side driver device SWH switches from the on state to the off state. When the switching of the high-side driver device SWH from the on state to the off state is completed, the current path to the inductive load LD switches from “the power supply node (Vcc)→the high-side driver device SWH→the inductive load LD” to “the ground node (GND)→the low-side freewheeling diode DIL→the inductive load LD,” and the output voltage Vout starts changing toward “−VDIL.”

Then, at time t2, the output voltage Vout falls below the reference voltages VrefL1 and VrefH1. Accordingly, the comparators 101L and 101H change the signal levels of the comparison result signals CL and CH, respectively, from the low level to the high level. In the high-side drive control section 11H, since the signal level of the high-side control signal

SinH is at the low level, the flip-flop 102H does not respond to the change of the comparison result signal CH from the low level to the high level, and keeps the signal level of the high-side drive signal SDH at the low level. Accordingly, the high-side driver device SWH is kept in the off state. On the other hand, in the low-side drive control section 11L, since the signal level of the low-side control signal SinL is at the high level, the flip-flop 102L changes the signal level of the low-side drive signal SDL from the low level to the high level in response to the change of the comparison result signal CL from the low level to the high level. Accordingly, the high-side driver device SWL switches from the off state to the on state. When the switching of the high-side driver device SWL from the off state to the on state is completed, the current path to the inductive load LD switches from “the ground node (GND)→the low-side freewheeling diode DIL→the inductive load LD” to “the ground node (GND)→the low-side driver device SWL→the inductive load LD,” and the output voltage Vout starts changing toward “−RL×I.”

Thereafter, at time t3, the output voltage Vout exceeds the reference voltages VrefL1 and VrefH1, and the signal levels of the comparison result signals CL and CH respectively change from the high level to the low level. Since the flip-flops 102L and 102H do not respond to the changes of the comparison result signals CL and CH from the high level to the low level, the signal level of the high-side drive signal SDH is kept at the low level, and the signal level of the low-side drive signal SDL is kept at the high level. Accordingly, the high-side driver device SWH is kept in the off state, and the low-side driver device SWL is kept in the on state.

Subsequently, at time t4, in the low-side drive control section 11L, the flip-flop 102L changes the signal level of the low-side drive signal SDL from the high level to the low level in response to a change of the low-side control signal SinL from the high level to the low level. Accordingly, the low-side driver device SWL switches from the on state to the off state. When the switching of the low-side driver device SWL from the on state to the off state is completed, the current path to the inductive load LD switches from “the ground node (GND)→the low-side driver device SWL→the inductive load LD” to “the ground node (GND)→the low-side freewheeling diode DIL→the inductive load LD,” and the output voltage Vout starts changing toward “−VDIL.”

Then, at time t5, the output voltage Vout falls below the reference voltages VrefL1 and VrefH1. Accordingly, the comparators 101L and 101H change the signal levels of the comparison result signals CL and CH, respectively, from the low level to the high level. In the low-side drive control section 11L, since the signal level of the low-side control signal SinL is at the low level, the flip-flop 102L does not respond to the change of the comparison result signal CL from the low level to the high level, and keeps the signal level of the low-side drive signal SDL at the low level. Accordingly, the low-side driver device SWL is kept in the off state. On the other hand, in the high-side drive control section 11H, since the signal level of the high-side control signal SinH is at the high level, the flip-flop 102H changes the signal level of the high-side drive signal SDH from the low level to the high level in response to the change of the comparison result signal CH from the low level to the high level. Accordingly, the high-side driver device SWH switches from the off state to the on state. When the switching of the high-side driver device SWH from the off state to the on state is completed, the current path to the inductive load LD switches from “the ground node (GND)→the low-side freewheeling diode DIL→the inductive load LD” to “the power supply node (Vcc)→the high-side driver device SWH→the inductive load LD,” and the output voltage Vout starts changing toward “Vcc−RH×I.”

Subsequently, at time t6, the output voltage Vout exceeds the reference voltages VrefL1 and VrefH1, and the signal levels of the comparison result signals CL and CH respectively change from the high level to the low level. Since the flip-flops 102L and 102H do not respond to the changes of the comparison result signals CL and CH from the high level to the low level, the signal level of the high-side drive signal SDH is kept at the high level, and the signal level of the low-side drive signal SDL is kept at the low level. Accordingly, the high-side driver device SWH is kept in the on state, and the low-side driver device SWL is kept in the off state.

In the configuration described above, it is possible to accurately set not only the duration of a first dead time (i.e., period P1 from when the high-side driver device SWH is switched from the on state to the off state to when the low-side driver device SWL is switched from the off state to the on state) but also the duration of a second dead time (i.e., period P2 from when the low-side driver device SWL is switched from the on state to the off state to when the high-side driver device SWH is switched from the off state to the on state). For example, the duration of each of the first dead time and the second dead time (i.e., period P1 and period P2) can be set at an ideal length (e.g., the minimum duration sufficient to prevent occurrence of shoot-through current).

### (Seventh Variation of First Embodiment)

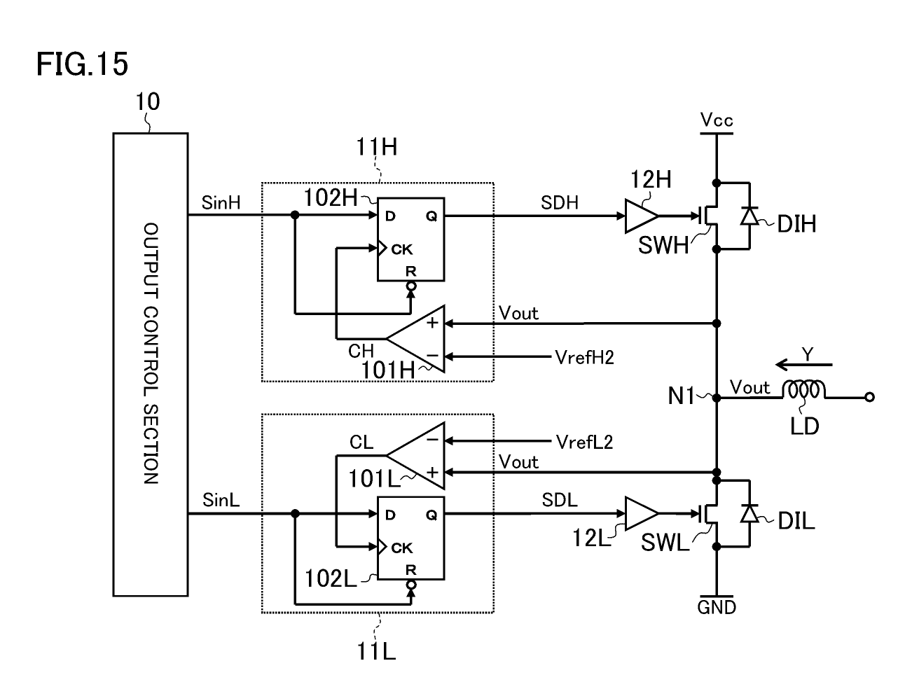

As illustrated in FIG. 15, in driving the inductive load LD such that the current-flow direction is in the suction direction Y, the comparator 101L may set the signal level of the comparison result signal CL at the low level when the output voltage Vout is lower than a reference voltage VrefL2, and set the signal level of the comparison result signal CL at the high level when the output voltage Vout is higher than the reference voltage VrefL2. The comparator 101H may set the signal level of the comparison result signal CH at the low level when the output voltage Vout is lower than a reference voltage VrefH2, and set the signal level of the comparison result signal CH at the high level when the output voltage Vout is higher than the reference voltage VrefH2.

### [Operation]

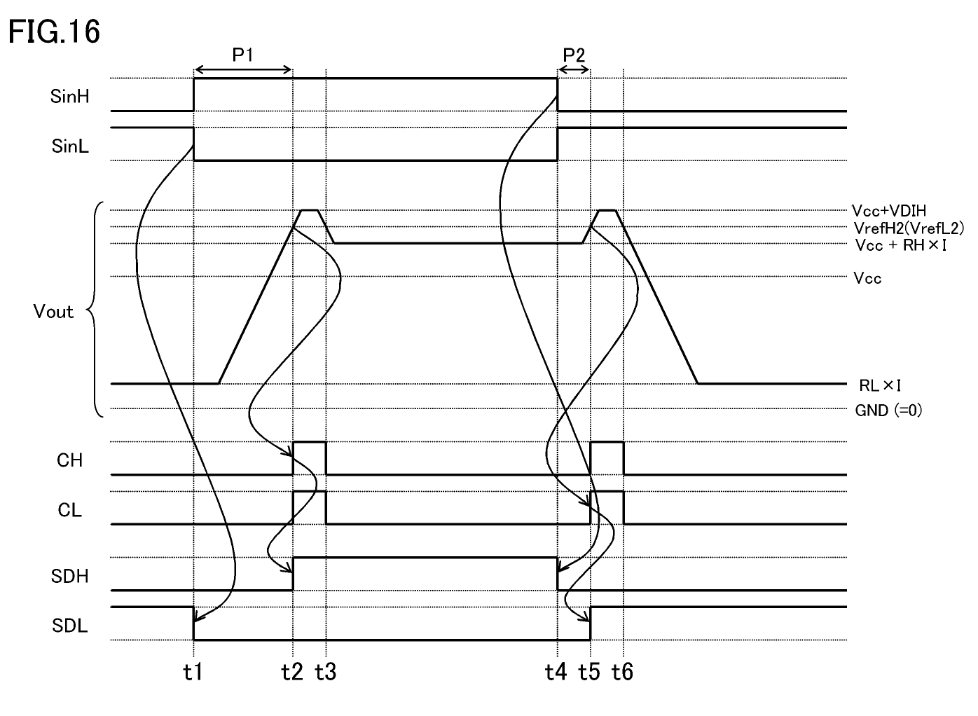

Referring now to FIG. 16, operation of the load driver system illustrated in FIG. 15 will be described. In this variation, it is assumed that the reference voltages VrefL2 and VrefH2 are the same voltage.

At time t1, in the low-side drive control section 11L, the flip-flop 102L changes the signal level of the low-side drive signal SDL from the high level to the low level in response to a change of the low-side control signal SinL from the high level to the low level. Accordingly, the low-side driver device SWL switches from the on state to the off state. When the switching of the low-side driver device SWL from the on state to the off state is completed, the current path from the inductive load LD switches from “the inductive load LD→the low-side driver device SWL→the ground node (GND)” to “the inductive load LD→the high-side freewheeling diode DIH→the power supply node (Vcc),” and the output voltage Vout starts changing toward “Vcc+VDIH.”

Then, at time t2, the output voltage Vout exceeds the reference voltages VrefL2 and VrefH2, and the signal levels of the comparison result signals CL and CH respectively change from the low level to the high level. In the low-side drive control section 11L, since the signal level of the low-side control signal SinL is at the low level, the flip-flop 102L does not respond to the change of the comparison result signal CL from the low level to the high level, and keeps the signal level of the low-side drive signal SDL at the low level. Accordingly, the low-side driver device SWL is kept in the off state. On the other hand, in the high-side drive control section 11H, the flip-flop 102H changes the signal level of the high-side drive signal SDH from the low level to the high level in response to the change of the comparison result signal CH from the low level to the high level. Accordingly, the high-side driver device SWH switches from the off state to the on state. When the switching of the high-side driver device SWH from the off state to the on state is completed, the current path from the inductive load LD switches from “the inductive load LD→the high-side freewheeling diode DIH→the power supply node (Vcc)” to “the inductive load LD→the high-side driver device SWH→the power supply node (Vcc),” and the output voltage Vout starts changing toward “Vcc+RH×I.”

Thereafter, at time t3, the output voltage Vout falls below the reference voltages VrefL2 and VrefH2, and the signal levels of the comparison result signals CL and CH respectively change from the high level to the low level. Since the flip-flops 102L and 102H do not respond to the changes of the comparison result signals CL and CH from the high level to the low level, the signal level of the low-side drive signal SDL is kept at the low level, and the signal level of the high-side drive signal SDH is kept at the high level. Accordingly, the low-side driver device SWL is kept in the off state, and the high-side driver device SWH is kept in the on state.

Subsequently, at time t4, in the high-side drive control section 11H, the flip-flop 102H changes the signal level of the high-side drive signal SDH from the high level to the low level in response to a change of the high-side control signal SinH from the high level to the low level. Accordingly, the high-side driver device SWH switches from the on state to the off state. When the switching of the high-side driver device SWH from the on state to the off state is completed, the current path from the inductive load LD switches from “the inductive load LD→the high-side driver device SWH→the power supply node (Vcc)” to “the inductive load LD→the high-side freewheeling diode DIH→the power supply node (Vcc),” and the output voltage Vout starts changing toward “Vcc +VDIH.”

Then, at time t5, the output voltage Vout exceeds the reference voltages VrefL2 and VrefH2, and the signal levels of the comparison result signals CL and CH respectively change from the low level to the high level. In the high-side drive control section 11H, since the signal level of the high-side control signal SinH is at the low level, the flip-flop 102H does not respond to the change of the comparison result signal CH from the low level to the high level, and keeps the signal level of the high-side drive signal SDH at the low level. Accordingly, the high-side driver device SWH is kept in the off state. On the other hand, in the low-side drive control section 11L, the flip-flop 102L changes the signal level of the low-side drive signal SDL from the low level to the high level in response to the change of the comparison result signal CL from the low level to the high level. Accordingly, the low-side driver device SWL switches from the off state to the on state. When the switching of the low-side driver device SWL from the off state to the on state is completed, the current path from the inductive load LD switches from “the inductive load LD→the high-side freewheeling diode DIH→the power supply node (Vcc)” to “the inductive load LD→the low-side driver device SWL→the ground node (GND),” and the output voltage Vout starts changing toward “RL×I.”

Subsequently, at time t6, the output voltage Vout falls below the reference voltages VrefL2 and VrefH2, and the signal levels of the comparison result signals CL and CH respectively change from the high level to the low level. Since the flip-flops 102L and 102H do not respond to the changes of the comparison result signals CL and CH from the high level to the low level, the signal level of the low-side drive signal SDL is kept at the high level, and the signal level of the high-side drive signal SDH is kept at the low level. Accordingly, the low-side driver device SWL is kept in the on state, and the high-side driver device SWH is kept in the off state.

In the configuration described above, it is also possible to accurately set not only the duration of a first dead time (i.e., period P1 from when the low-side driver device SWL is switched from the on state to the off state to when the high-side driver device SWH is switched from the off state to the on state) but also the duration of a second dead time (i.e., period P2 from when the high-side driver device SWH is switched from the on state to the off state to when the low-side driver device SWL is switched from the off state to the on state).

### (Eighth Variation of First Embodiment)

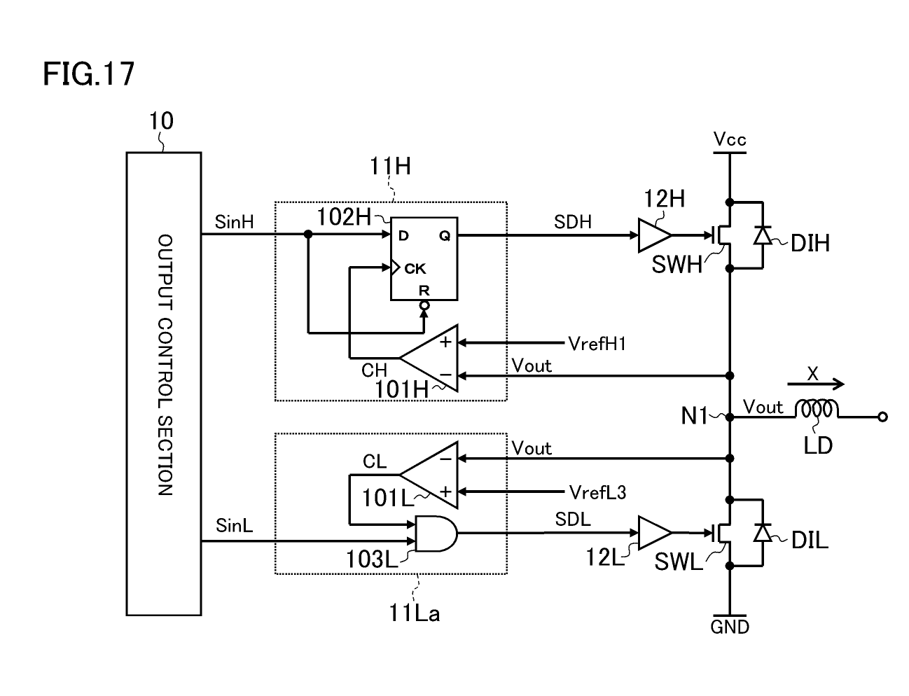

As illustrated in FIG. 17, the load driver system may include the low-side drive control section 11La illustrated in FIG. 5, instead of the low-side drive control section 11L illustrated in FIG. 13. Other part of the configuration is the same as in the load driver system illustrated in FIG. 13. In FIG. 17, the load driver system drives the inductive load LD such that the current-flow direction of the inductive load LD is in the discharge direction X.

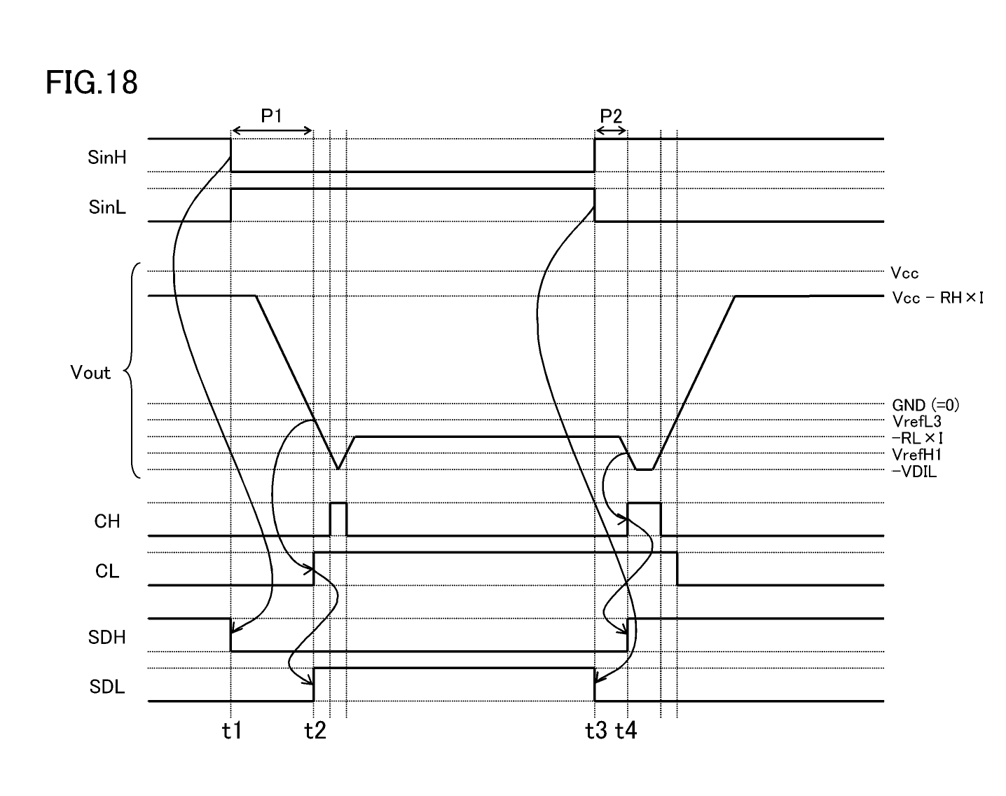

As shown in FIG. 18, at time t1, the high-side drive control section 11H changes the signal level of the high-side drive signal SDH from the high level to the low level in response to a change of the high-side control signal SinH from the high level to the low level. Then, at time t2, when the low-side drive control section 11La detects that the output voltage Vout falls below a reference voltage VrefL3, the low-side drive control section 11La changes the signal level of the low-side drive signal SDL from the low level to the high level. Thereafter, at time t3, the low-side drive control section 11La changes the signal level of the low-side drive signal SDL from the high level to the low level in response to a change of the low-side control signal SinL from the high level to the low level. Subsequently, at time t4, when the high-side drive control section 11H detects that the output voltage Vout falls below the reference voltage VrefH1, the high-side drive control section 11H changes the signal level of the high-side drive signal SDH from the low level to the high level.

In the configuration described above, it is also possible to accurately set not only the duration of a first dead time (i.e., period P1 from when the high-side driver device SWH is switched from the on state to the off state to when the low-side driver device SWL is switched from the off state to the on state) but also the duration of a second dead time (i.e., period P2 from when the low-side driver device SWL is switched from the on state to the off state to when the high-side driver device SWH is switched from the off state to the on state).

### (Ninth Variation of First Embodiment)

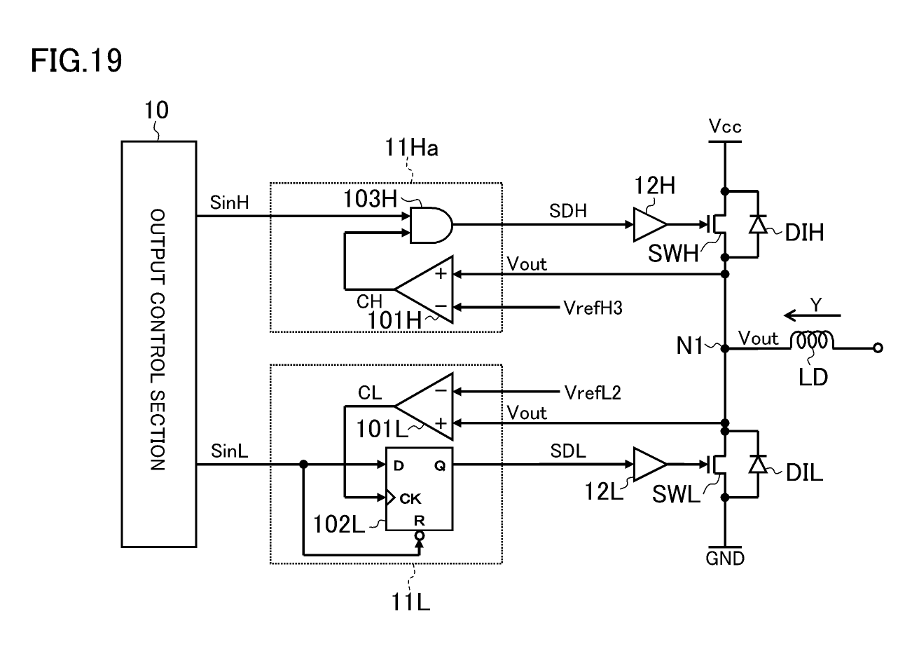

As illustrated in FIG. 19, the load driver system may include the high-side drive control section 11Ha illustrated in FIG. 11, instead of the high-side drive control section 11H illustrated in FIG. 15. Other part of the configuration is the same as in the load driver system illustrated in FIG. 15. In FIG. 19, the load driver system drives the inductive load LD such that the current-flow direction of the inductive load LD is in the suction direction Y.

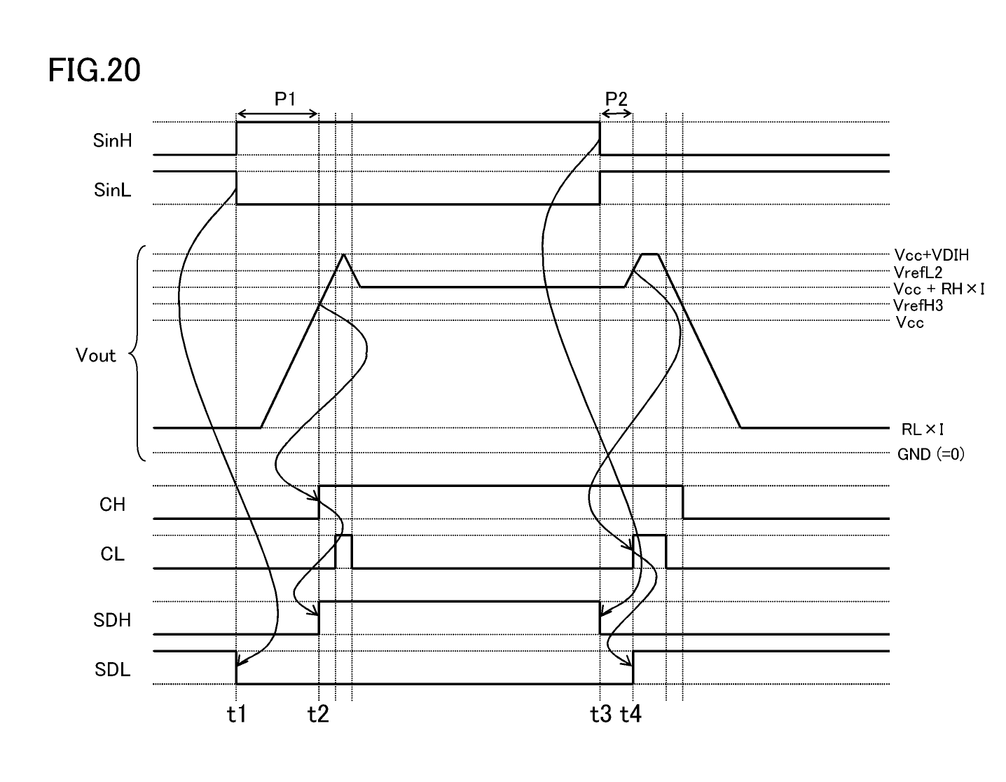

As shown in FIG. 20, at time t1, the low-side drive control section 11L changes the signal level of the low-side drive signal SDL from the high level to the low level in response to a change of the low-side control signal SinL from the high level to the low level. Then, at time t2, when the high-side drive control section 11Ha detects that the output voltage Vout exceeds the reference voltage VrefH3, the high-side drive control section 11Ha changes the signal level of the high-side drive signal SDH from the low level to the high level. Thereafter, at time t3, the high-side drive control section 11Ha changes the signal level of the high-side drive signal SDH from the high level to the low level in response to a change of the high-side control signal SinH from the high level to the low level. Subsequently, at time t4, when the low-side drive control section 11L detects that the output voltage Vout exceeds the reference voltage VrefL2, the low-side drive control section 11L changes the signal level of the low-side drive signal SDL from the low level to the high level.

In the configuration described above, it is also possible to accurately set not only the duration of a first dead time (i.e., period P1 from when the low-side driver device SWL is switched from the on state to the off state to when the high-side driver device SWH is switched from the off state to the on state) but also the duration of a second dead time (i.e., period P2 from when the high-side driver device SWH is switched from the on state to the off state to when the low-side driver device SWL is switched from the off state to the on state).

### Second Embodiment

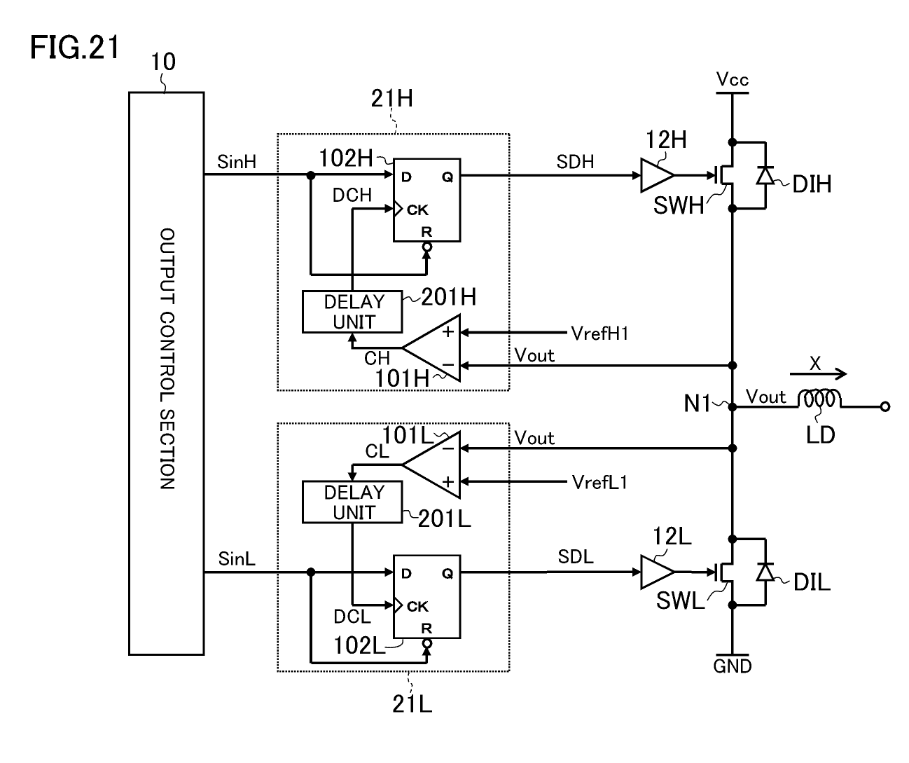

FIG. 21 illustrates an example of a configuration of a load driver system according to a second embodiment. The load driver system includes a low-side drive control section 21L and a high-side drive control section 21H, instead of the low-side drive control section 11L and the high-side drive control section 11H illustrated in FIG. 13. Other part of the configuration is the same as in the load driver system illustrated in FIG. 13.

### [Low-Side Drive Control Section and High-Side Drive Control Section]

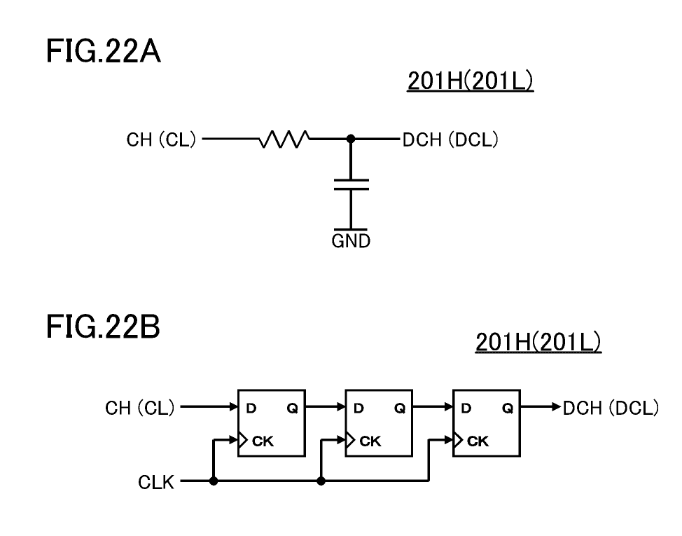

The low-side drive control section 21L and the high-side drive control section 21H respectively include delay units 201L and 201H, in addition to the components of the low-side drive control section 11L and the high-side drive control section 11H illustrated in FIG. 13. Other part of the configuration is the same as in the configurations of the low-side drive control section 11L and the high-side drive control section 11H illustrated in FIG. 13. The delay units 201L and 201H delay comparison result signals CL and CH from the comparators 101L and 101H for a predetermined delay time, and supply the delayed signals as comparison result signals DCL and DCH to flip-flops 102L and 102H, respectively. For example, each of the delay units 201L and 201H may be made of a low-pass filter as illustrated in FIG. 22A, or may be made of a shift register which sequentially delays comparison signal CL (or CH) in synchronization with a clock CLK as illustrated in FIG. 22B.

### [Operation]

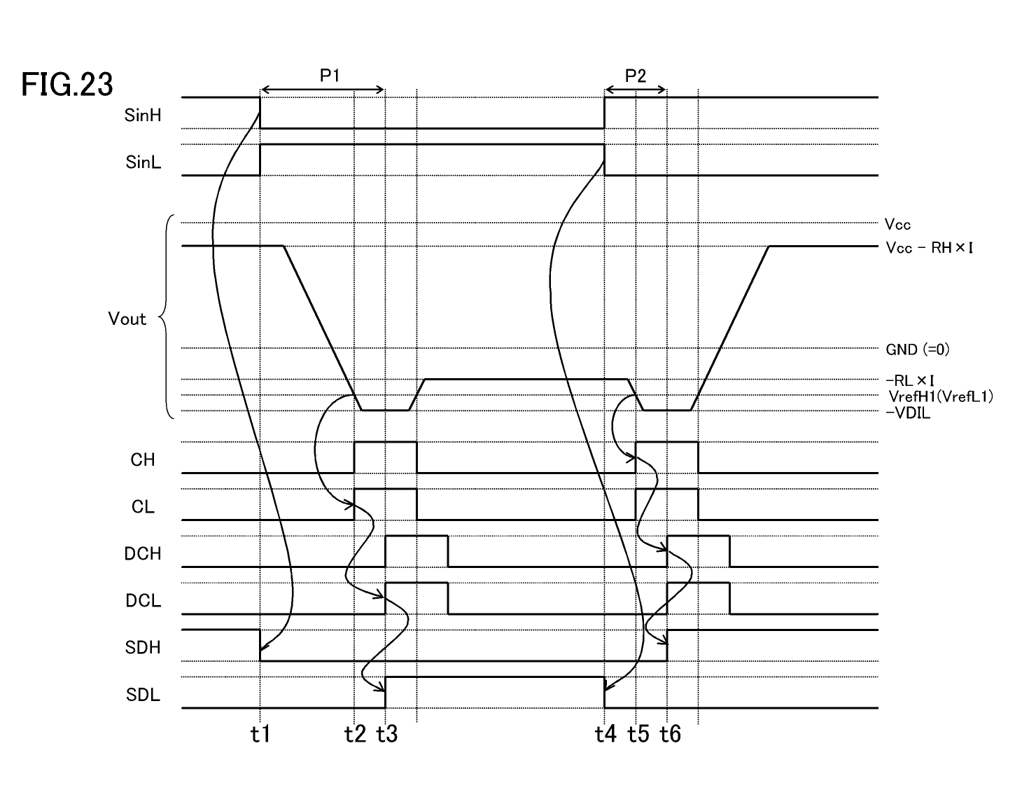

Referring now to FIG. 23, operation of the load driver system illustrated in FIG. 21 will be described. In this embodiment, it is assumed that reference voltages VrefL1 and VrefH1 are the same voltage.

At time t1, in the high-side drive control section 21H, the flip-flop 102H changes the signal level of a high-side drive signal SDH from the high level to the low level in response to a change of a high-side control signal SinH from the high level to the low level.

Then, at time t2, the output voltage Vout falls below the reference voltages VrefL1 and VrefH1, and the comparators 101L and 101H change the signal levels of the comparison result signals CL and CH, respectively, from the low level to the high level.

Thereafter, at time t3, the delay units 201L and 201H change the signal levels of the comparison result signals DCL and DCH, respectively, from the low level to the high level. Accordingly, in the low-side drive control section 21L, since the signal level of a low-side control signal SinL is at the high level, the flip-flop 102L changes the signal level of the low-side drive signal SDL from the low level to the high level in response to the change of the comparison result signal DCL from the low level to the high level. On the other hand, in the high-side drive control section 21H, since the signal level of the high-side control signal SinH is at the low level, the flip-flop 102H does not respond to the change of the high comparison result signal DCH from the low level to the high level, and keeps the signal level of the high-side drive signal SDH at the low level.

Subsequently, at time t4, in the low-side drive control section 21L, the flip-flop 102L changes the signal level of the low-side drive signal SDL from the high level to the low level in response to a change of the low-side control signal SinL from the high level to the low level.

Then, at time t5, the output voltage Vout falls below the reference voltages VrefL1 and VrefH1, and the comparators 101L and 101H change the signal levels of the comparison result signals CL and CH, respectively, from the low level to the high level.

Subsequently, at time t6, the delay units 201L and 201H change the signal levels of the comparison result signals DCL and DCH, respectively, from the low level to the high level. Accordingly, in the high-side drive control section 21H, since the signal level of the high-side control signal SinH is at the high level, the flip-flop 102H changes the signal level of the high-side drive signal SDH from the low level to the high level in response to the change of the comparison result signal DCH from the low level to the high level. On the other hand, in the low-side drive control section 21L, since the signal level of the low-side control signal SinL is at the low level, the flip-flop 102L does not respond to the change of the comparison result signal DCL from the low level to the high level, and keeps the signal level of the low-side drive signal SDL at the low level.

In the manner described above, when the low-side drive control section 21L detects that the output voltage Vout reaches the reference voltage VrefL1 at time t1, the low-side drive control section 21L changes the signal level of the low-side drive signal SDL from the low level to the high level after a lapse of a predetermined delay time (i.e., a period from time t2 to time t3), thereby switching the low-side driver device SWL from the off state to the on state. Further, at time t4, the low-side drive control section 21L changes the low-side drive signal SDL from the high level to the low level, thereby switching the low-side driver device SWL from the on state to the off state. On the other hand, at time t1, the high-side drive control section 21H changes the high-side drive signal SDH from the high level to the low level, thereby switching the high-side driver device SWH from the on state to the off state. At time t4, when the high-side drive control section 21H detects that the output voltage Vout reaches the reference voltage VrefH1, the high-side drive control section 21H changes the signal level of the high-side drive signal SDH from the low level to the high level after a lapse of a predetermined delay time (i.e., a period from time t5 to time t6), thereby switching the high-side driver device SWH from the off state to the on state.

As described above, a first dead time (i.e., period P1 from when the high-side driver device SWH is switched from the on state to the off state to when the low-side driver device SWL is switched from the off state to the on state) includes a delay time (i.e., a period from time t2 to time t3). Thus, adjustment of the duration of the delay time (i.e., the period from time t2 to time t3) allows the duration of the first dead time (i.e., period P1) to be adjusted. In the same manner, a second dead time (i.e., period P2 from the switching of the low-side driver device SWL from the on state to the off state to the switching of the high-side driver device SWH from the off state to the on state) includes a delay time (i.e., a period from time t5 to time t6). Thus, adjustment of the duration of the delay time (i.e., the period from time t5 to time t6) allows the duration of the second dead time (i.e., period P2) to be adjusted.

The low-side drive control section 21L may include a delay unit which delays an output of the flip-flop 102L and outputs the delayed signal as the low-side drive signal SDL, instead of the delay unit 201L. In the same manner, the high-side drive control section 21H may include a delay unit which delays an output of the flip-flop 102H and outputs the delayed signal as the high-side drive signal SDH, instead of the delay unit 201H.

The low-side drive control section 11La illustrated in FIG. 5 or 17 may further include a delay unit which delays the comparison result signal CL from the comparator 101L and outputs the delayed signal to the AND circuit 103L, or may further include a delay unit which delays an output of the AND circuit 103L and outputs the delayed signal as the low-side drive signal SDL. In the same manner, the high-side drive control section 11Ha illustrated in FIG. 11 or 19 may further include a delay unit which delays the comparison result signal CH from the comparator 101H and outputs the delayed signal to the AND circuit 103H, or may further include a delay unit which delays an output of the AND circuit 103H and outputs the delayed signal as the high-side drive signal SDH.

In driving the inductive load LD such that the current-flow direction is in the discharge direction X, the load driver system illustrated in FIG. 21 may include one of the high-side drive control sections 13H and 11H illustrated in FIGS. 1 and 7 instead of the high-side drive control section 21H, or may include one of the low-side drive control sections 11L, 11La, and 13L illustrated in FIGS. 1, 5, and 7 instead of the low-side drive control section 21L.

In driving the inductive load LD such that the current-flow direction is in the suction direction Y, in the low-side drive control section 21L and the high-side drive control section 21H illustrated in FIG. 21, the comparators 101L and 101H may set the signal levels of the comparison result signals CL and CH at the low level when the output voltage Vout is lower than the reference voltages VrefL2 and VrefH2, and set the signal levels of the comparison result signals CL and CH at the high level when the output voltage Vout is higher than the reference voltages VrefL2 and VrefH2. In this case, the load driver system illustrated in FIG. 21 may include one of the high-side drive control sections 13H, 11H, and 11Ha illustrated in FIGS. 3, 9, and 11 instead of the high-side drive control section 21H, and may include one of the low-side drive control sections 11L and 13L illustrated in FIGS. 3 and 9 instead of the low-side drive control section 21L.

### Third Embodiment

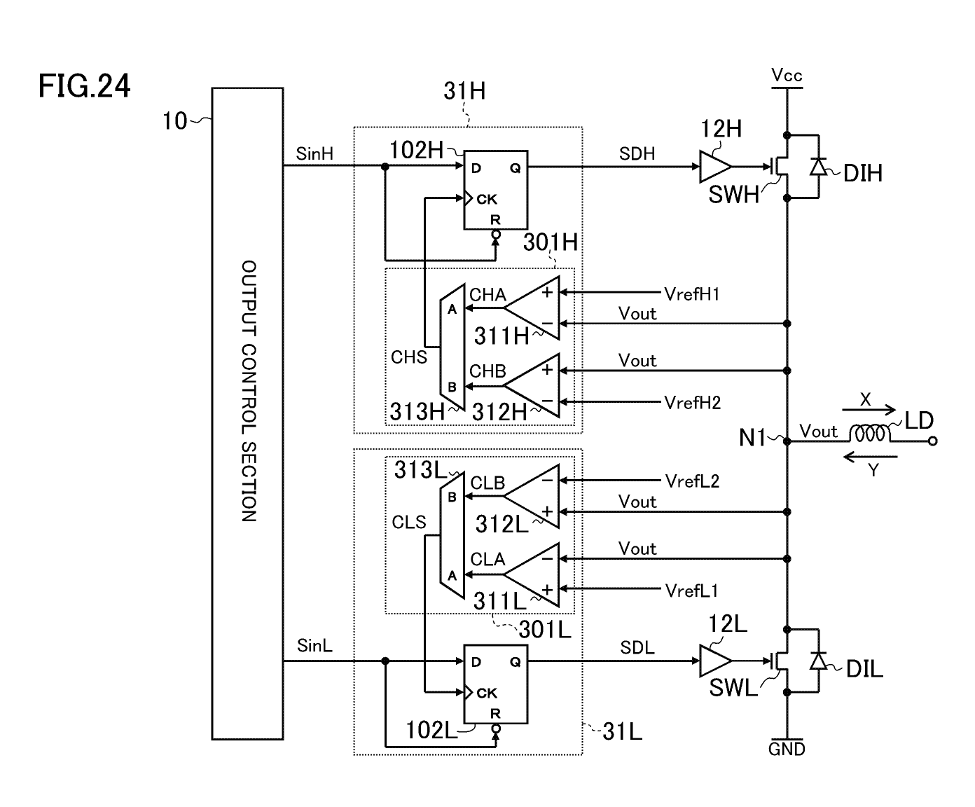

FIG. 24 illustrates an example of a configuration of a load driver system according to a third embodiment. The load driver system includes a low-side drive control section 31L and a high-side drive control section 31H, instead of the low-side drive control section 11L and the high-side drive control section 11H illustrated in FIG. 13. Other part of the configuration is the same as in the load driver system illustrated in FIG. 13.

### [Low-Side Drive Control Section]

The low-side drive control section 31L has first and second comparison modes, and is switchable between the first and second comparison modes (by, for example, external control). In the first comparison mode, when a first switching time comes (e.g., when the signal level of a low-side control signal SinL changes from the low level to the high level and the signal level of a high-side control signal SinH changes from the high level to the low level), the low-side drive control section 31L detects that an output voltage Vout falls below a predetermined first comparison voltage (which is, in this embodiment, a reference voltage VrefL1), and then switches a low-side driver device SWL from the off state to the on state. Then, when a second switching time comes (e.g., when the signal level of the low-side control signal SinL changes from the high level to the low level and the signal level of the high-side control signal SinH changes from the low level to the high level), the low-side drive control section 31L switches the low-side driver device SWL from the on state to the off state. In the second comparison mode, when the first switching time comes, the low-side drive control section 31L detects that the output voltage Vout exceeds a predetermined second comparison voltage (which is, in this embodiment, a reference voltage VrefL2), and then switches the low-side driver device SWL from the off state to the on state. Then, when the second switching time comes, the low-side drive control section 31L switches the low-side driver device SWL from the on state to the off state.

### [High-Side Drive Control Section]

The high-side drive control section 31H has third and fourth comparison modes, and is switchable between the third and fourth comparison modes (by, for example, external control). In the third comparison mode, when a first switching time comes (e.g., when the signal level of the low-side control signal SinL changes from the low level to the high level and the signal level of the high-side control signal SinH changes from the high level to the low level), the high-side drive control section 31H switches the high-side driver device SWH from the on state to the off state. Then, when a second switching time comes (e.g., when the signal level of the low-side control signal SinL changes from the high level to the low level and the signal level of the high-side control signal SinH changes from the low level to the high level), the high-side drive control section 31H detects that the output voltage Vout falls below a predetermined third comparison voltage (which is, in this embodiment a reference voltage VrefH1), and then switches the high-side driver device SWH from the off state to the on state. In the fourth comparison mode, when the first switching time comes, the high-side drive control section 31H switches the high-side driver device SWH from the on state to the off state. Then, when the second switching time comes, the high-side drive control section 31H detects that the output voltage Vout exceeds a fourth comparison voltage (which is, in this embodiment, a reference voltage VrefH2), and then switches the high-side driver device SWH from the off state to the on state.

For example, the low-side drive control section 31L and the high-side drive control section 31H include comparison switches 301L and 301H, respectively, instead of the comparators 101L and 101H illustrated in FIG. 13. Other parts of the configurations are the same as those of the low-side drive control section 11L and the high-side drive control section 11H illustrated in FIG. 13.

The comparison switch 301L includes comparators 311L and 312L and a selector 313L. The comparator 311L sets the signal level of a comparison result signal CLA at the low level when the output voltage Vout is higher than the reference voltage VrefL1, and sets the signal level of the comparison result signal CLA at the high level when the output voltage Vout is lower than the reference voltage VrefL1. The comparator 312L sets the signal level of a comparison result signal CLB at the low level when the output voltage Vout is lower than the reference voltage VrefL2, and sets the signal level of the comparison result signal CLB at the high level when the output voltage Vout is higher than the reference voltage VrefL2. The selector 313L selects one of the comparison result signals CLA and CLB as a comparison result signal CLS, and supplies the comparison result signal CLS to a flip-flop 102L.

The comparator 311L corresponds to the comparator 101L illustrated in FIG. 1, and the comparator 312L corresponds to the comparator 101L illustrated in FIG. 3. Accordingly, when the selector 313L selects the comparison result signal CLA, the low-side drive control section 31L operates in the same manner as the low-side drive control section 11L illustrated in FIG. 1. When the selector 313L selects the comparison result signal CLB, the low-side drive control section 31L operates in the same manner as the low-side drive control section 11L illustrated in FIG. 3.

The comparison switch 301H includes comparators 311H and 312H and a selector 313H. The comparator 311H sets the signal level of a comparison result signal CHA at the low level when the output voltage Vout is higher than the reference voltage VrefH1, and sets the signal level of the comparison result signal CHA at the high level when the output voltage Vout is lower than the reference voltage VrefH1. The comparator 312H sets the signal level of a comparison result signal CHB at the low level when the output voltage Vout is lower than the reference voltage VrefH2, and sets the signal level of the comparison result signal CHA at the high level when the output voltage Vout is higher than the reference voltage VrefH2. The selector 313H selects one of the comparison result signals CHA and CHB as a comparison result signal CHS, and supplies the comparison result signal CHS to a flip-flop 102H.

The comparator 311H corresponds to the comparator 101H illustrated in FIG. 7, and the comparator 312H corresponds to the comparator 101H illustrated in FIG. 9. Accordingly, when the selector 313H selects the comparison result signal CHA, the high-side drive control section 31H operates in the same manner as the high-side drive control section 11H illustrated in FIG. 7. When the selector 313H selects the comparison result signal CHB, the high-side drive control section 31H operates in the same manner as the high-side drive control section 11H illustrated in FIG. 9.

For example, in driving an inductive load LD such that the current-flow direction of the inductive load is in a discharge direction X, the selectors 313L and 313H may select the comparison result signals CLA and CHA as the comparison result signals CLS and CHS, respectively. Accordingly, the load driver system illustrated in FIG. 24 operates in the same manner as the load driver system illustrated in FIG. 13 (see FIG. 14). On the other hand, in driving the inductive load LD such that the current-flow direction of the inductive load is in a suction direction Y, the selectors 313L and 313H may select the comparison result signals CLB and CHB as the comparison result signals CLS and CHS, respectively. Accordingly, the load driver system illustrated in FIG. 24 operates in the same manner as the load driver system illustrated in FIG. 15 (see FIG. 16).

As described above, it is possible to set the current-flow direction of the inductive load LD in an intended direction.

### (Variation of Third Embodiment)

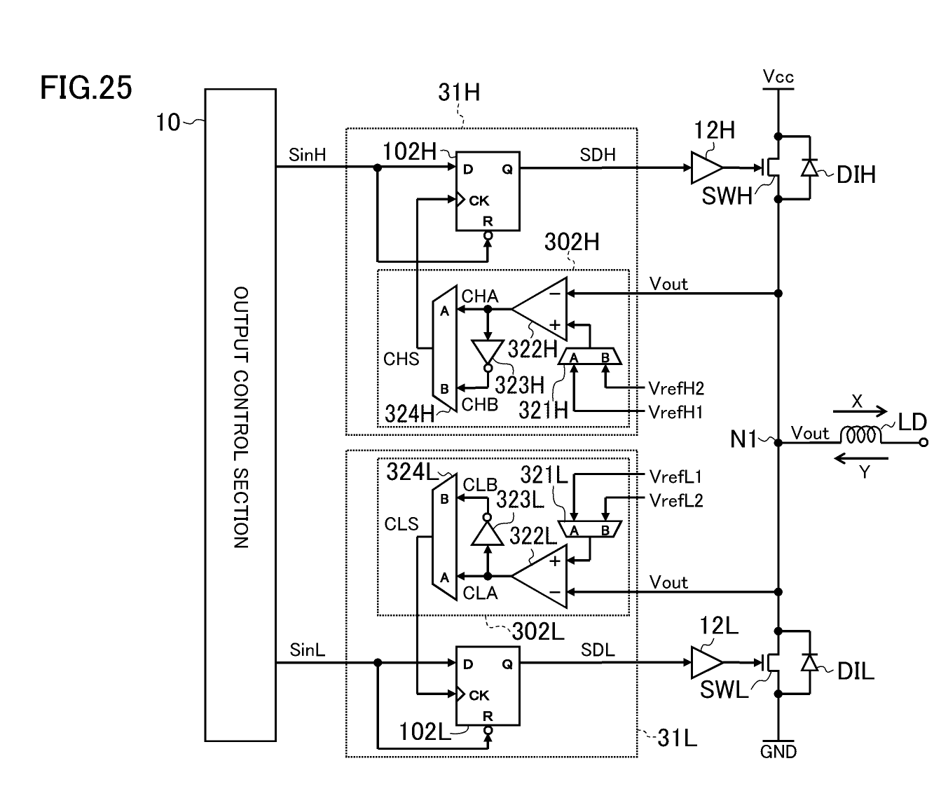

As illustrated in FIG. 25, the low-side drive control section 31L and the high-side drive control section 31H may include comparison switches 302L and 302H, respectively, instead of the comparison switches 301L and 301H illustrated in FIG. 24. Other parts of the configurations are the same as those of the low-side drive control section 31L and the high-side drive control section 31H illustrated in FIG. 24.

The comparison switch 302L includes a selector 321L, a comparator 322L, an inverter 323L, and a selector 324L. The selector 321L selects one of the reference voltages VrefL1 and VrefL2. The comparator 322L sets the signal level of the comparison result signal CLA at the low level when the output voltage Vout is higher than the voltage selected by the selector 321L, and sets the comparison result signal CLA at the high level when the output voltage Vout is lower than the voltage selected by the selector 321L. The inverter 323L inverts the comparison result signal CLA, and outputs the inverted signal as the comparison result signal CLB. The selector 324L selects one of the comparison result signals CLA and CLB as the comparison result signal CLS, and supplies the comparison result signal CLS to the flip-flop 102L.

The low-side drive control section 31L operates in the same manner as the low-side drive control section 11L illustrated in FIG. 1 when the selectors 321L and 324L select the reference voltage VrefL1 and the comparison result signal CLA, respectively, and operates in the same manner as the low-side drive control section 11L illustrated in FIG. 3 when the selectors 321L and 324L select the reference voltage VrefL2 and the comparison result signal CLB, respectively.

The comparison switch 302H includes a selector 321H, a comparator 322H, an inverter 323H, and a selector 324H. The selector 321H selects one of the reference voltages VrefH1 and VrefH2. The comparator 322H sets the comparison result signal CHA at the low level when the output voltage Vout is higher than the voltage selected by the selector 321L, and sets the comparison result signal CHA at the high level when the output voltage Vout is lower than the voltage selected by the selector 321H. The inverter 323H inverts the comparison result signal CHA, and outputs the inverted signal as the comparison result signal CHB. The selector 324H selects one of the comparison result signals CHA and CHB as the comparison result signal CHS, and supplies the comparison result signal CHS to the flip-flop 102H.

The high-side drive control section 31H operates in the same manner as the high-side drive control section 11H illustrated in FIG. 7 when the selectors 321H and 324H select the reference voltage VrefH1 and the comparison result signal CHA, respectively, and operates in the same manner as the high-side drive control section 11H illustrated in FIG. 9 when the selectors 321H and 324H select the reference voltage VrefH2 and the comparison result signal CHB, respectively.

The configuration described above can enable the circuit scale to be made smaller than those of the low-side drive control section 31L and the high-side drive control section 31H including the comparison switches 301L and 301H illustrated in FIG. 24.

The low-side drive control section 31L and the high-side drive control section 31H may further include the delay units 201L and 201H illustrated in FIG. 21, or may further include delay units which delay outputs of the flip-flops 102L and 102H and output the delayed signals as the low-side drive signal SDL and the high-side drive signal SDH, respectively.

The load driver system illustrated in FIG. 24 may include the high-side drive control section 13H illustrated in FIG. 1 instead of the high-side drive control section 31H, or may include the low-side drive control section 13L illustrated in FIG. 7 instead of the low-side drive control section 31L.

### Fourth Embodiment

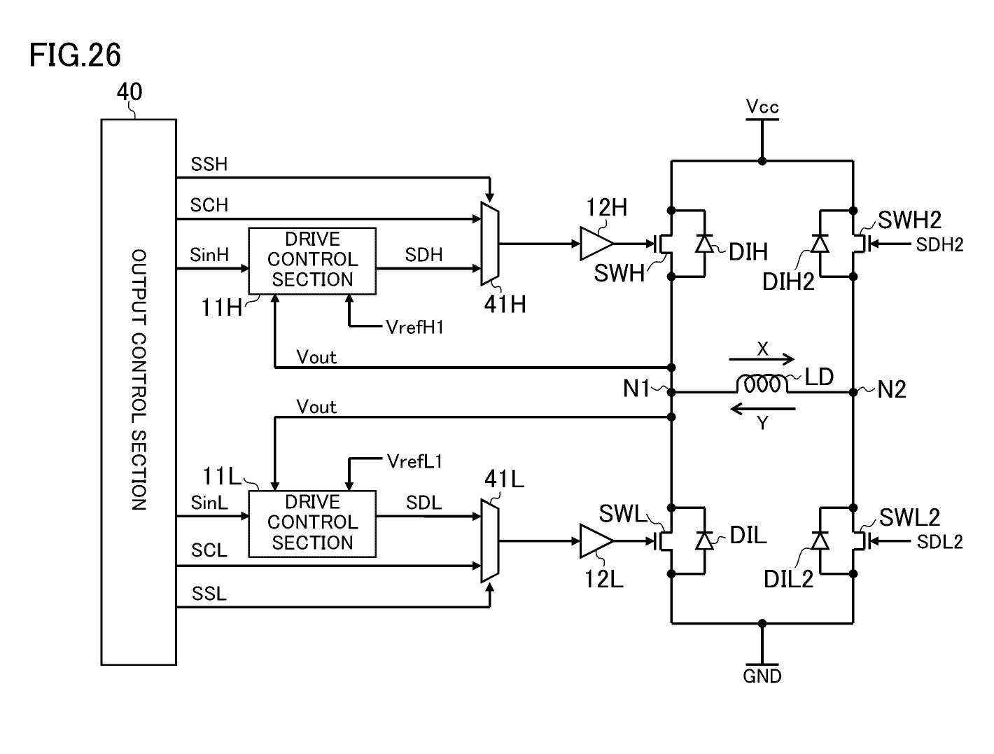

FIG. 26 illustrates an example of a configuration of a load driver system according to a fourth embodiment. The load driver system includes an output control section 40, a low-side drive switch 41L, and a high-side drive switch 41H, instead of the output control section 10 illustrated in FIG. 13. Other part of the configuration is the same as in the configuration of the load driver system illustrated in FIG. 13. The inductive load LD is connected between an output node N1 and an output node N2. The output node N2 is connected to a low-side driver device SWL2, a low-side freewheeling diode DIL2, a high-side driver device SWH2, and a high-side freewheeling diode DIH2. The low-side driver device SWL2 and the low-side freewheeling diode DIL2 are connected in parallel between the output node N2 and a ground node. The high-side driver device SWH2 and the high-side freewheeling diode DIH2 are connected in parallel between the output node N2 and a power supply node. That is, an H-bridge circuit is formed.

### [Output Control Section]

In the same manner as the output control section 10 illustrated in FIG. 13, the output control section 40 outputs a low-side control signal SinL and a high-side control signal SinH for determining switching times of on/off of the low-side driver device SWL and the high-side driver device SWH. The output control section 40 also outputs a low-side drive switching signal SSL for switching the driving mode of the low-side drive switch 41L, a high-side drive switching signal SSH for switching the driving mode of the high-side drive switch 41H, a low-side control signal SCL for fixing the low-side driver device SWL in one of the on state and the off state, and a high-side control signal SCH for fixing the high-side driver device SWH in one of the on state and the off state.

### [Low-Side Drive Switch]

The low-side drive switch 41L has first and second driving modes, and is switchable between the first and second driving modes according to the low-side drive switching signal SSL. In the first driving mode, the low-side drive switch 41L supplies a low-side drive signal SDL from a low-side drive control section 11L to a low-side driver device SWL through a low-side pre-driver 12L, thereby allowing the low-side drive control section 11L to control on/off of the low-side driver device SWL. In the second driving mode, the low-side drive switch 41L supplies the low-side control signal SCL from the output control section 40 to the low-side driver device SWL through the low-side pre-driver 12L, thereby fixing the low-side driver device SWL in one of the on state and the off state.

### [High-Side Drive Control Section]

The high-side drive switch 41H has third and fourth driving modes, and is switchable between the third and fourth driving modes according to the high-side drive switching signal SSH. In the third driving mode, the high-side drive switch 41H supplies the high-side drive signal SDH from the high-side drive control section 11H to the high-side driver device SWH through the high-side pre-driver 12H, thereby allowing the high-side drive control section 11H to control on/off of the high-side driver device SWH. In the fourth driving mode, the high-side drive switch 41H supplies the high-side control signal SCH from the output control section 40 to the high-side driver device SWH through the high-side pre-driver 12H, thereby fixing the high-side driver device SWH in one of the on state and the off state.

For example, in the H-bridge circuit illustrated in FIG. 26, in driving an inductive load LD such that the current-flow direction is in the suction direction Y, the low-side drive switch 41L and the high-side drive switch 41H respectively supply the low-side control signal SCL and the high-side control signal SCH from the output control section 40 to the low-side driver device SWL and the high-side driver device SWH, thereby fixing the low-side driver device SWL in the off state, and also fixing the high-side driver device SWH in the on state. In this case, on/off of the low-side driver device SWL2 and the high-side driver device SWH2 is controlled. On the other hand, in the H-bridge circuit illustrated in FIG. 26, in driving the inductive load LD such that the current-flow direction is in the discharge direction X, the low-side driver device SWL2 is fixed in the on state, and the high-side driver device SWH2 is fixed in the off state. In this case, the low-side drive switch 41L and the high-side drive switch 41H respectively supply the low-side drive signal SDL from the low-side drive control section 11L and the high-side drive signal SDH from the high-side drive control section 11H to the low-side driver device SWL and the high-side driver device SWH, thereby allowing the low-side drive control section 11L and the high-side drive control section 11H to control on/off of the low-side driver device SWL and the high-side driver device SWH.

The foregoing configuration can provide not only driving with a synchronous rectification driving method but also driving with a driving method except for the synchronous rectification driving method. Accordingly, a system including two or more output circuits such as an H-bridge circuit (e.g., a circuit including a low-side driver device, a high-side driver device, a low-side freewheeling diode, and a high-side freewheeling diode) can be driven with a synchronous rectification method.

The load driver system illustrated in FIG. 26 may include one of the low-side drive control sections 11L, 11La, 13L, 21L, 31L, and 31L illustrated in FIGS. 3, 5, 7, 21, 24, and 25 instead of the low-side drive control section 11L, or may include one of the high-side drive control sections 13L, 11H, 11Ha, 21H, 31H, and 31H illustrated in FIGS. 1, 9, 11, 21, 24, and 25.

In the manner described above, the load driver system can accurately set the duration of a dead time according to variations of the output voltage, and thus, is useful for, for example, a driver circuit having a synchronous rectification function such as a motordriver circuit.

The foregoing embodiments and their variations have been set forth merely for purposes of preferred examples in nature, and are not intended to limit the scope, applications, and use of the invention.

What is claimed is:

1. A load driver system for driving an inductive load, the load driver system comprising:
a first driver device and a first diode connected in parallel between an output node and a first voltage node, the output node being connected to the inductive load, the first voltage node being configured to receive a first voltage;
a second driver device and a second diode connected in parallel between the output node and a second voltage node, the second voltage node being configured to receive a second voltage;
a first drive control section configured to switch the first driver device from an off state to an on state, after detecting that an output voltage at the output node reaches a predetermined first reference voltage, when a first switching time comes, and to switch the first driver device from the on state to the off state when a second switching time comes; and
a second drive control section configured to switch the second driver device from an on state to an off state when the first switching time comes, and to switch the second driver device from the off state to the on state when the second switching time comes.

2. The load driver system of claim 1, wherein
the first drive control section includes
a comparator configured to deactivate a comparison result signal when the output voltage is higher than the first reference voltage, and to activate the comparison result signal when the output voltage is lower than the first reference voltage, and
a latch configured to receive a first control signal which is activated when the first switching time comes and is deactivated when the second switching time comes, to activate a first drive signal to be supplied to the first driver device in synchronization with activation of the comparison result signal when the first control signal is activated, and to deactivate the first drive signal when the first control signal is deactivated, and
the first driver device is in the on state when the first drive signal is activated, and is in the off state when the first drive signal is deactivated.

3. The load driver system of claim 1, wherein
the first drive control section includes
a comparator configured to deactivate a comparison result signal when the output voltage is lower than the first reference voltage, and to activate the comparison result signal when the output voltage is higher than the first reference voltage, and
a latch configured to receive a first control signal which is activated when the first switching time comes and is deactivated when the second switching time comes, to activate a first drive signal to be supplied to the first driver device in synchronization with activation of the comparison result signal when the first control signal is activated, and to deactivate the first drive signal when the first control signal is deactivated, and
the first driver device is in the on state when the first drive signal is activated, and is in the off state when the first drive signal is deactivated.

4. The load driver system of claim 1, wherein the first voltage is lower than the second voltage,
the first drive control section includes
a comparator configured to deactivate a comparison result signal when the output voltage is higher than the first reference voltage, and to activate the comparison result signal when the output voltage is lower than the first reference voltage, and
a first logic circuit configured to receive a first control signal which is activated when the first switching time comes and is deactivated when the second switching time comes, to activate a first drive signal to be supplied to the first driver device when both of the first control signal and the comparison result signal are activated, and to deactivate the first drive signal when at least one of the first control signal and the comparison result signal is deactivated, and
the first driver device is in the on state when the first drive signal is activated, and is in the off state when the first drive signal is deactivated.

5. The load driver system of claim 1, wherein the first voltage is higher than the second voltage,
the first drive control section includes
a comparator configured to deactivate a comparison result signal when the output voltage is lower than the first reference voltage, and to activate the comparison result signal when the output voltage is higher than the first reference voltage, and
a first logic circuit configured to receive a first control signal which is activated when the first switching time comes and is deactivated when the second switching time comes, to activate a first drive signal to be supplied to the first driver device when both of the first control signal and the comparison result signal are activated, and to deactivate the first drive signal when at least one of the first control signal and the comparison result signal is deactivated, and
the first driver device is in the on state when the first drive signal is activated, and is in the off state when the first drive signal is deactivated.

6. The load driver system of claim 1, wherein the first drive control section switches the first driver device from the off state to the on state after a lapse of a predetermined first delay time, after detecting that the output voltage reaches the first reference voltage, when the first switching time comes, and switches the first driver device from the on state to the off state when the second switching time comes.

7. The load driver system of claim 1, wherein the first drive control section has first and second comparison modes,
in the first comparison mode, the first drive control section switches the first driver device from the off state to the on state, after detecting that the output voltage falls below a predetermined first comparison voltage, when the first switching time comes, whereas the first drive control section switches the first driver device from the on state to the off state when the second switching time comes, and
in the second comparison mode, the first drive control section switches the first driver device from the off state to the on state, after detecting that the output voltage exceeds a predetermined second comparison voltage, when the first switching time comes, whereas the first drive control section switches the first driver device from the on state to the off state when the second switching time comes.

8. The load driver system of claim 1, wherein the second drive control section switches the second driver device from the on state to the off state when the first switching time comes, whereas the second drive control section switches the second driver device from the off state to the on state, after detecting that the output voltage reaches a predetermined second reference voltage, when the second switching time comes.

9. The load driver system of claim 8, wherein the second drive control section switches the second driver device from the on state to the off state when the first switching time comes, whereas the second drive control section switches the second driver device from the off state to the on state after a lapse of a predetermined second delay time, after detecting that the output voltage reaches the second reference voltage, when the second switching time comes.

10. The load driver system of claim 8, wherein the second drive control section has third and fourth comparison modes,
in the third comparison mode, the second drive control section switches the second driver device from the on state to the off state when the first switching time comes, whereas the second drive control section switches the second driver device from the off state to the on state, after detecting that the output voltage falls below a predetermined third comparison voltage, when the second switching time comes, and
in the fourth comparison mode, the second drive control section switches the second driver device from the on state to the off state when the first switching time comes, whereas the second drive control section switches the second driver device from the off state to the on state, after detecting that the output voltage exceeds a predetermined fourth comparison voltage, when the second switching time comes.

11. The load driver system of claim 1, further comprising:
a first drive switch having first and second driving modes, allowing the first drive control section to control on/off of the first driver device in the first driving mode, and fixing the first driver device in one of the on state and the off state in the second driving mode; and
a second drive switch having third and fourth driving modes, allowing the second drive control section to control on/off of the second driver device in the third driving mode, and fixing the second driver device in one of the on state and the off state in the fourth driving mode.
